(19) United States
(12) Patent Application Publication
(10) Pub. No.: US 2016/0217730 A1
(43) Pub. Date: Jul. 28, 2016

(54) ELECTRO LUMINESCENT DISPLAY PANEL AND ELECTRONIC APPARATUS

(71) Applicant: Sony Corporation, Tokyo (JP)

(72) Inventors: Takayuki Taneda, Kanagawa (JP); Katsuhide Uchino, Kanagawa (JP); Yukihito Iida, Kanagawa (JP); Mitsuru Asano, Kanagawa (JP)

(21) Appl. No.: 15/087,551

(22) Filed: Mar. 31, 2016

Related U.S. Application Data
(63) Continuation of application No. 14/813,863, filed on Jul. 30, 2015.
Application No. 14/813,863 is a continuation of application No. 14/445,104, filed on Jul. 29, 2014.
Application No. 14/445,104 is a continuation of application No. 12/292,339, filed on Nov. 17, 2008.

(30) Foreign Application Priority Data
Nov. 28, 2007 (JP) 2007-307042

(51) Int. Cl. G09G 3/325; H01L 51/52; H01L 27/32

(52) U.S. Cl. CPC G09G 3/325; H01L 27/3279; H01L 51/52; H01L 2251/5315; G09G 2300/0819; G09G 2310/08; G09G 2320/0209

(57) ABSTRACT

An EL display panel having a pixel structure corresponding to an active-matrix drive system, the EL display panel including a current supply line configured to be connected to a plurality of pixel circuits in common, line width of an intersection part of the current supply line with a signal line being smaller than line width of the other part of the current supply line.

### CROSS REFERENCES TO RELATED APPLICATIONS

This is a Continuation of application Ser. No. 14/813,863, filed Jul. 30, 2015, which is a Continuation of application Ser. No. 14/445,104, filed Jul. 29, 2014, which is a Continuation of application Ser. No. 12/292,339, filed Nov. 17, 2008, which in turn claims priority from Japanese Application Number 2007-307042 filed in the Japan Patent Office on Nov. 28, 2007, the entire contents of which being incorporated herein by reference.

### BACKGROUND OF THE INVENTION

1. Field of the Invention

The invention to be described in this specification relates to the structure of an Electro luminescent (EL) display panel whose driving is controlled based on an active-matrix drive system. The invention to be proposed by this specification also has aspects as an EL display panel and electronic apparatus.

2. Description of Related Art

FIG. 1 shows a general circuit block configuration of an active-matrix-driven organic EL panel. As shown in FIG. 1, an organic EL panel 1 includes a pixel array part 3, and a write control line driver 5 and a horizontal selector 7 as drive circuits for the pixel array part 3. In the pixel array part 3, pixel circuits 9 are disposed at the respective intersections of signal lines DTL and write control lines WSL.

An organic EL element is a current-driven light-emitting element. Therefore, in the organic EL panel, the grayscales of color representation are controlled through control of the amounts of the currents that flow through the organic EL elements corresponding to the respective pixels.

FIG. 2 shows one of the simplest circuit configurations of this kind of pixel circuit 9. This pixel circuit 9 includes a write transistor T1, a drive transistor T2, and a hold capacitor Cs.

The write transistor T1 is a thin film transistor that controls writing of a signal potential Vsig dependent upon the grayscale of the corresponding pixel to the hold capacitor Cs. The drive transistor T2 is a thin film transistor that supplies a drive current Ids to an organic EL element OLED based on a gate-source voltage Vgs dependent upon the signal potential Vsig held in the hold capacitor Cs. In the configuration of FIG. 2, the write transistor T1 is formed of an N-channel thin film transistor, and the drive transistor T2 is formed of a P-channel thin film transistor.

In the configuration of FIG. 2, the source electrode of the drive transistor T2 is connected to a current supply line (power supply line) to which a supply potential Vcc is fixedly applied. Therefore, the drive transistor T2 always operates in the saturation region. Specifically, the drive transistor T2 operates as a constant current source that supplies the drive current dependent upon the signal potential Vsig to the organic EL element OLED. The drive current Ids supplied by the drive transistor T2 is represented by the following equation.

Ids=k·μ·(Vgs−Vth)²/2

In this equation, μ denotes the mobility of the majority carrier in the drive transistor T2. Vth denotes the threshold voltage of the drive transistor T2. k is a coefficient represented as (W/L)·Cox. W denotes the channel width, L denotes the channel length, and Cox denotes the gate capacitance per unit area.

In the pixel circuit having this configuration, the drain voltage of the drive transistor T2 changes along with aging change in the I-V characteristic of the organic EL element, shown in FIG. 3.

However, because the gate-source voltage Vgs is kept constant, no change occurs in the amount of the current supplied to the organic EL element, and thus the light-emission luminance can be kept constant.

Examples of documents about an organic EL panel display employing the active-matrix drive system include Japanese Patent Laid-open Nos. 2003-255856, 2003-271095, 2004-133240, 2004-029791, and 2004-093682.

### SUMMARY OF THE INVENTION

Depending on the kind of thin film process, the circuit configuration shown in FIG. 2 can not be employed in some cases. Specifically, the existing thin film processes involve the case in which a P-channel thin film transistor can not be employed. In such a case, the P-channel transistor as the drive transistor T2 is replaced by an N-channel thin film transistor.

FIG. 4 shows the configuration of this kind of pixel circuit. In this configuration, the source electrode of the drive transistor T2 is connected to the anode terminal of the organic EL element OLED. Therefore, this pixel circuit 9 involves a problem that the gate-source voltage Vgs of the drive transistor T2 varies in linkage with change in the I-V characteristic of the organic EL element along with time elapse. This change in the gate-source voltage Vgs leads to change in the drive current amount, resulting in change in the light-emission luminance.

In addition, the threshold voltage and the mobility of the drive transistor T2 included in each pixel circuit differ from pixel to pixel. The difference in the threshold voltage and the mobility of the drive transistor T2 appears as variation in the drive current value, which causes variation of the light-emission luminance of the pixels.

Therefore, if the pixel circuit shown in FIG. 4 is employed, establishment of a drive method that allows stable light-emission characteristics irrespective of aging change is required. At the same time, realization of a panel structure that offers high display quality is required.

The present inventors propose an EL display panel including a current supply line connected to a plurality of pixel circuits in common as an EL display panel having a pixel structure corresponding to an active-matrix drive system. In this EL display panel, the line width of an intersection part of the current supply line with a signal line is smaller than the line width of the other part of the current supply line.

According to this panel structure, without increasing the area of the intersection part of the current supply line with the signal line, the line width of the current supply line other than the intersection part can be increased. This means an advantage that the interconnect resistance of the current supply line as a whole can be decreased. As a result, potential change of the current supply line dependent upon a displayed image and pixel positions can be reduced.

Larger effects can be expected by this panel structure when driving of the current supply line is controlled with potentials of binary values or more values. In the case in which a fixed potential is not applied to the current supply line, potential change of the current supply line is easily transmitted to the signal line via the coupling capacitance formed at the intersection part with the signal line if the area of the intersection part with the signal line is large.

However, according to the above-described panel structure, the area of the intersection part between the current supply line and the signal line can be decreased with respect to the current drive capability. Thus, the influence of potential change of the current supply line on the signal line can be decreased. As a result, the potential change transmitted to the signal line is small, and thus the influence on the potential that is being written can be minimized. Consequently, the lowering of the display quality can be suppressed.

The proposed panel structure is more effective when the pixel structure has a top-emission structure. In the top-emission structure, the forming layer of the current supply line does not intersect with the output paths of light rays. Therefore, the line width of the current supply line other than the intersection part with the signal line can be increased without influence on the aperture ratio.

Larger effects can be expected by the proposed panel structure when the timing of potential change of the current supply line corresponding to a certain row exists in a period of writing of a signal line potential on another row. As described above, the area of the intersection part with the signal line is small although potential change of the current supply line is transmitted via the intersection part with the signal line. Thus, the influence on the writing of the signal line potential in the pixel circuit on another row can be minimized.

In particular, if mobility correction is carried out in the period of the writing of the signal line potential, the accuracy of the mobility correction for the drive transistor can be enhanced. In addition, if threshold correction is carried out, the accuracy of the threshold correction for the drive transistor can be enhanced. Thus, the above-described panel structure is effective for suppressing the lowering of the display quality.

The present inventors also propose electronic apparatus including an EL display panel having the above-described panel structure.

The electronic apparatus includes the EL display panel, a system controller that controls the operation of the entire system, and an operation input unit that accepts an operation input to the system controller.

Employing the embodiments of the present invention proposed by the present inventors makes it possible to increase the line width of the current supply line other than the intersection part of the current supply line with the signal line without increasing the area of the intersection part. This increase in the line width allows reduction in the interconnect resistance of the current supply line as a whole. As a result, the image quality can be improved through suppression of the potential drop of the current supply line dependent upon a displayed image and pixel positions.

Furthermore, the area of the intersection part between the current supply line and the signal line can be decreased. This can suppress the amount of transmission of potential change from the current supply line to the signal line. Thus, erroneous writing to the pixel circuit due to change in the signal line potential can be prevented.

### BRIEF DESCRIPTION OF THE DRAWINGS

FIG. 1 is a diagram for explaining the functional block configuration of an organic EL panel;

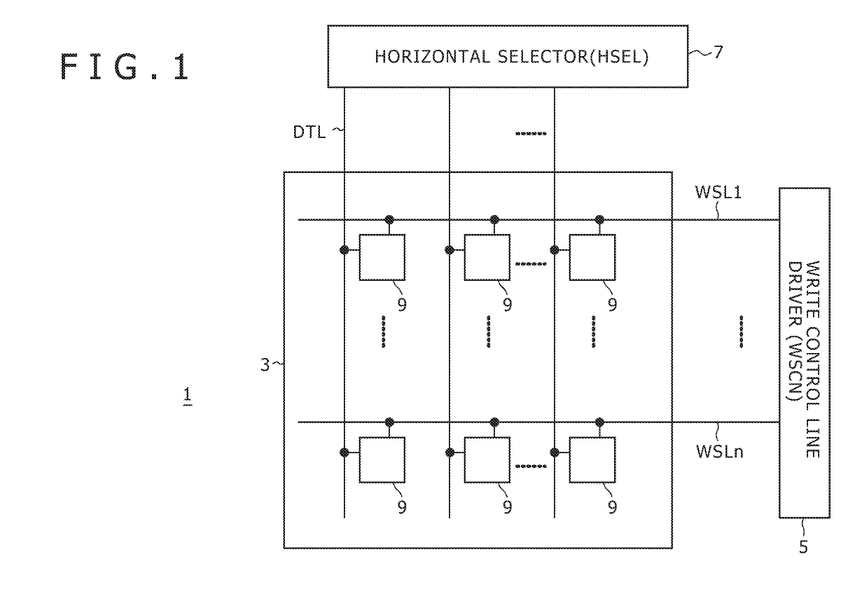

FIG. 2 is a diagram for explaining the connection relationship between a pixel circuit and drive circuits;

FIG. 3 is a diagram for explaining aging change in the I-V characteristic of an organic EL element;

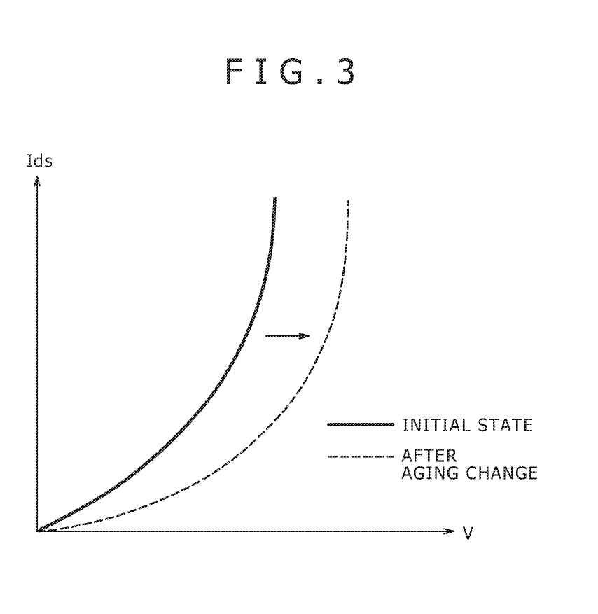

FIG. 4 is a diagram showing another pixel circuit example;

FIG. 5 is a diagram showing an appearance configuration example of an organic EL panel;

FIG. 6 is a diagram showing a system configuration example of the organic EL panel;

FIG. 7 is a diagram for explaining the connection relationship between pixel circuits and drive circuits;

FIG. 8 is a diagram showing a configuration example of a pixel circuit according to a first form example;

FIGS. 9A to 9E are diagrams showing drive operation examples according to the first form example;

FIG. 10 is a diagram for explaining the operation state of the pixel circuit;

FIG. 11 is a diagram for explaining the operation state of the pixel circuit;

FIG. 12 is a diagram for explaining the operation state of the pixel circuit;

FIG. 13 is a diagram for explaining the operation state of the pixel circuit;

FIG. 14 is a diagram showing the rise of the source potential;

FIG. 15 is a diagram for explaining the operation state of the pixel circuit;

FIG. 16 is a diagram showing difference in the degree of the rise of the source potential due to difference in the mobility;

FIG. 17 is a diagram for explaining the operation state of the pixel circuit;

FIG. 18 is a diagram for explaining a shading phenomenon;

FIG. 19 is a diagram for explaining the cause of the occurrence of the shading phenomenon;

FIGS. 20A and 20B are diagrams for explaining a crosstalk phenomenon;

FIG. 21 is a diagram for explaining the cause of the occurrence of the crosstalk phenomenon;

FIG. 22 is a diagram showing the layout of the pixel circuit corresponding to the first form example;

FIG. 23 is a diagram showing an improved layout example of the pixel circuit;

FIGS. 24A to 24F are diagrams for explaining the influence of potential change of a current supply line on mobility correction;

FIGS. 25A to 25G are diagrams for explaining the influence of potential changes of current supply lines on threshold correction;

FIGS. 26A to 26D are diagrams for explaining the principle of the occurrence of the influence on the threshold correction;

FIG. 27 is a diagram showing the layout of a pixel circuit proposed as a second form example;

FIGS. 28A to 28F are diagrams for explaining improvement in the mobility correction;

FIGS. 29A to 29G are diagrams for explaining improvement in the threshold correction;

FIG. 30 is a diagram for explaining a top-emission structure example;

FIG. 31 is a diagram showing a configuration example of an organic EL panel according to the second form example;

FIG. 32 is a diagram showing the connection relationship between pixel circuits and drive circuits according to the second form example;

FIG. 33 is a diagram showing a configuration example of the pixel circuit according to the second form example;

FIG. 34 is a diagram showing a conceptual configuration example of electronic apparatus;

FIG. 35 is a diagram showing a commercial product example of electronic apparatus;

FIGS. 36A and 36B are diagrams showing commercial product examples of electronic apparatus;

FIG. 37 is a diagram showing a commercial product example of electronic apparatus,

FIGS. 38A and 38B are diagrams showing a commercial product examples of electronic apparatus; and

FIG. 39 is a diagram showing a commercial product example of electronic apparatus.

### DETAILED DESCRIPTION OF THE PREFERRED EMBODIMENTS

The following description will deal with an example in which an embodiment of the present invention is applied to an active-matrix-driven organic EL panel.

Well-known or publicly-known techniques in the related-art technical field are applied to part that is not particularly illustrated or described in the present specification. It should be noted that the following form examples of the present invention are merely embodiment examples of the invention, and the invention is not limited thereto.

### (A) Appearance Configuration

In this specification, not only a display panel obtained by forming a pixel array part and drive circuits on the same substrate by using the same semiconductor process but also e.g. one obtained by mounting drive circuits manufactured as application-specific ICs on a substrate on which a pixel array part is formed is referred to as an organic EL panel.

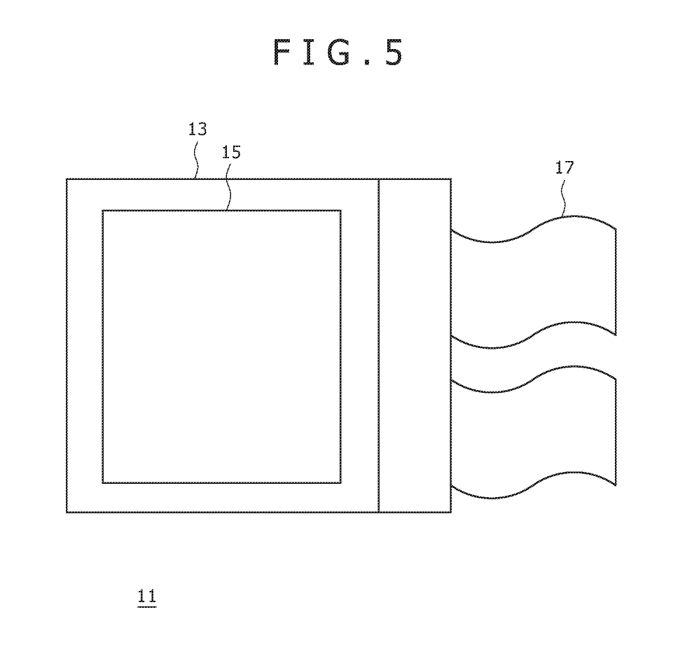

FIG. 5 shows an appearance configuration example of an organic EL panel. An organic EL panel 11 has a structure obtained by bonding a counter unit 15 to the formation area of a pixel array part of a support substrate 13.

The support substrate 13 is composed of glass, plastic, or another material, and an organic EL layer, a protective film, and so on are formed on the surface thereof. The base of the counter unit 15 is composed of glass, plastic, or another transparent material. In the organic EL panel 11, a flexible printed circuit (FPC) 17 for inputting/outputting of signals and so on from/to the external to/from the support substrate 13 is disposed.

### (B) First Form Example

### (B-1) System Configuration

The following description will deal with a system configuration example of the organic EL panel 11 in which variation in the characteristics of the drive transistor T2 formed of an N-channel thin film transistor is prevented and the number of elements included in the pixel circuit is small.

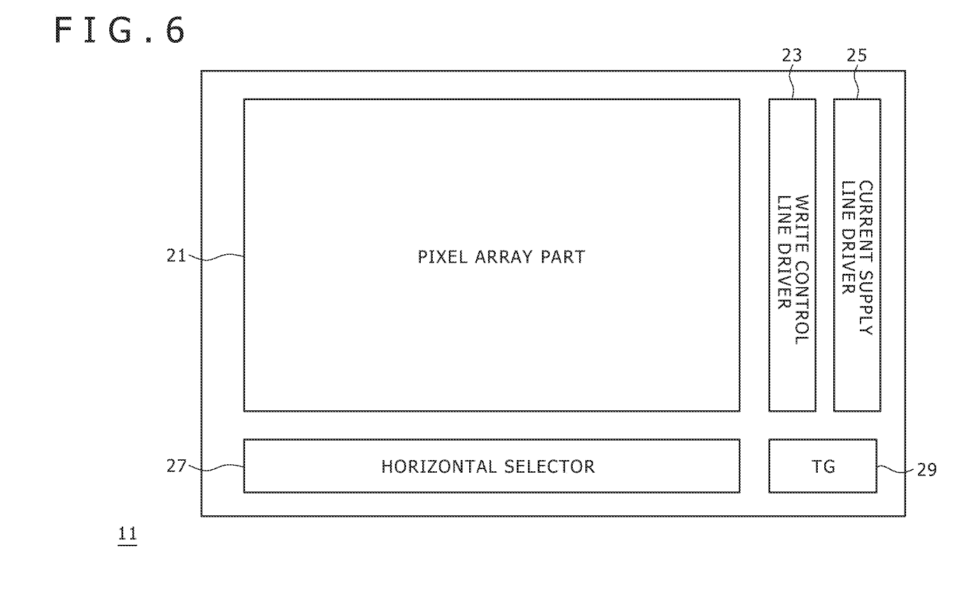

FIG. 6 shows the system configuration example of the organic EL panel 11. The organic EL panel 11 shown in FIG. 6 includes a pixel array part 21, and a write control line driver 23, a current supply line driver 25, a horizontal selector 27, and a timing generator 29 as drive circuits for the pixel array part 21.

The pixel array part 21 has a matrix structure in which sub-pixels are disposed at the respective intersections of signal lines DTL and write control lines WSL. The sub-pixel is the minimum unit of the pixel structure of one pixel. For example, one pixel as a white unit is composed of three sub-pixels (R, G, B) that are different from each other in the organic EL material.

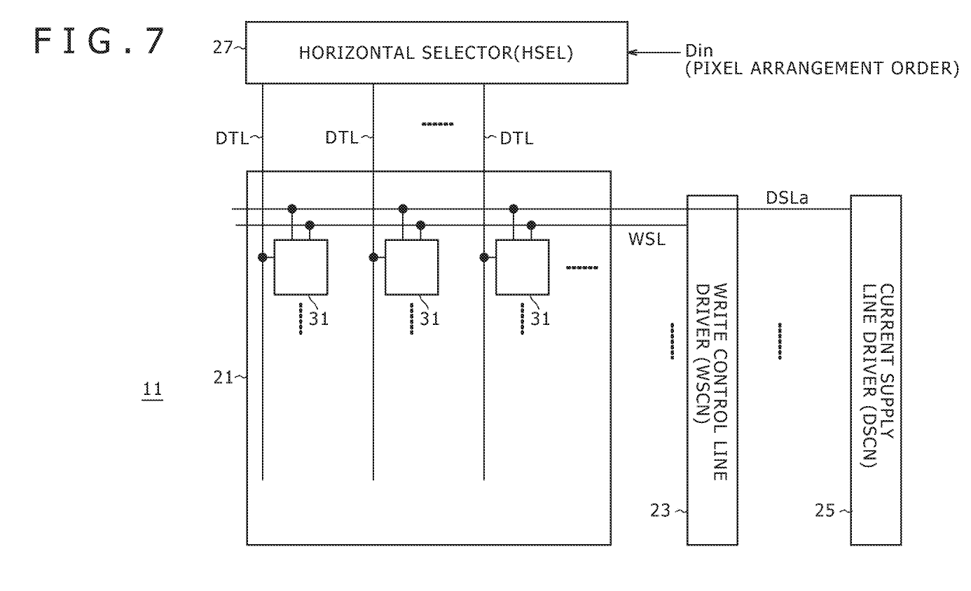

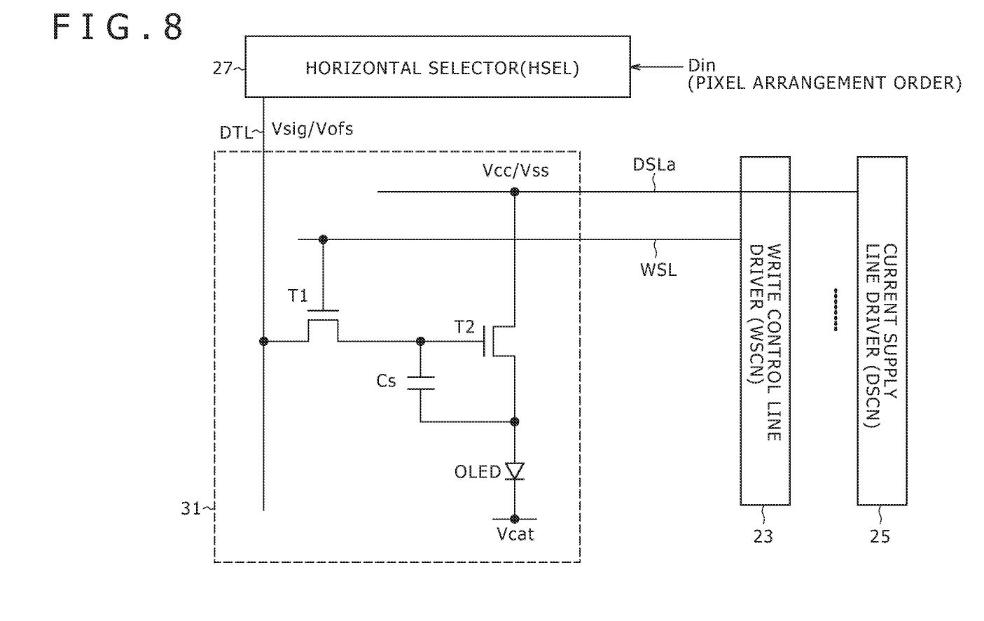

FIG. 7 shows the connection relationship between the pixel circuits corresponding to the sub-pixels and the respective drive circuits. FIG. 8 shows the internal configuration of the pixel circuit to be proposed as a first form example. The pixel circuit shown in FIG. 8 includes two N-channel thin film transistors T1 and T2 and one hold capacitor Cs.

Also in this circuit configuration, the write control line driver 23 controls opening/closing of the write transistor T1 via the write control line WSL, to thereby control writing of a signal line potential to the hold capacitor Cs. The write control line driver 23 includes shift registers having the same number of output stages as the vertical solution.

The current supply line driver 25 controls, in a binary manner, a current supply line DSLa connected to one main electrode of the drive transistor T2, and controls the operation in the pixel circuit through cooperative operation together with other drive circuits. The operation in the pixel circuit encompasses not only the light-emission/non-light-emission operation of the organic EL element but also operation for correction against characteristic variations. In this form example, the correction against the characteristic variations means correction against the deterioration of the uniformity due to variations in the threshold voltage and the mobility of the drive transistor T2.

The horizontal selector 27 applies, to the signal line DTL, a signal potential Vsig dependent upon pixel data Din or an offset potential Vofs for threshold voltage correction. The horizontal selector 27 includes shift registers having the same number of output stages as the horizontal solution, latch circuits corresponding to the respective output stages, a D/A conversion circuit, a buffer circuit, and a selector.

The timing generator 29 produces the timing pulses necessary for the driving of the write control line WSL, the current supply line DSLa, and the signal line DTL.

### (B-2) Drive Operation Example

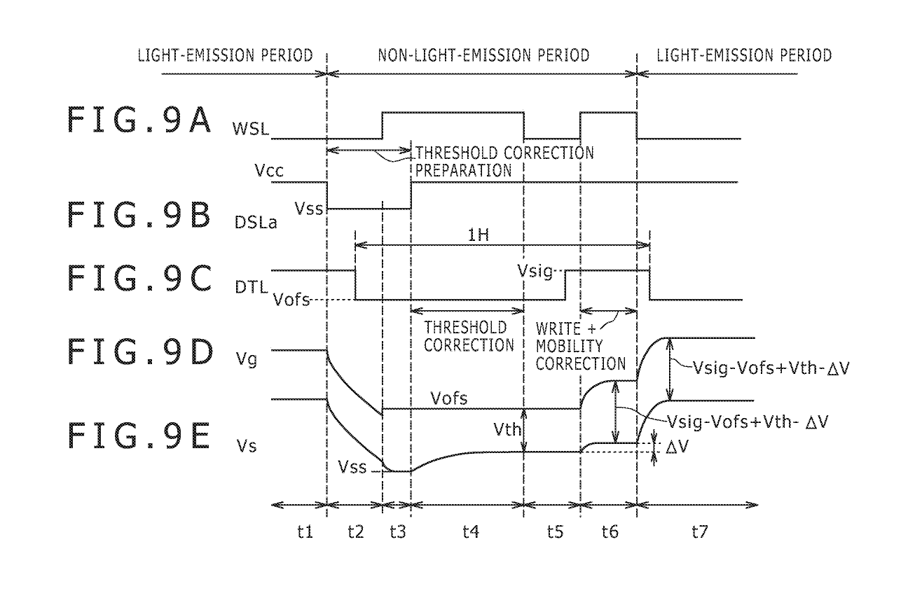

FIGS. 9A to 9E show drive operation examples of the pixel circuit shown in FIG. 8. In FIGS. 9A to 9E, of two kinds of supply potentials applied to the current supply line DSLa, the higher potential (light-emission potential) is represented as Vcc, and the lower potential (non-light-emission potential) is represented as Vss.

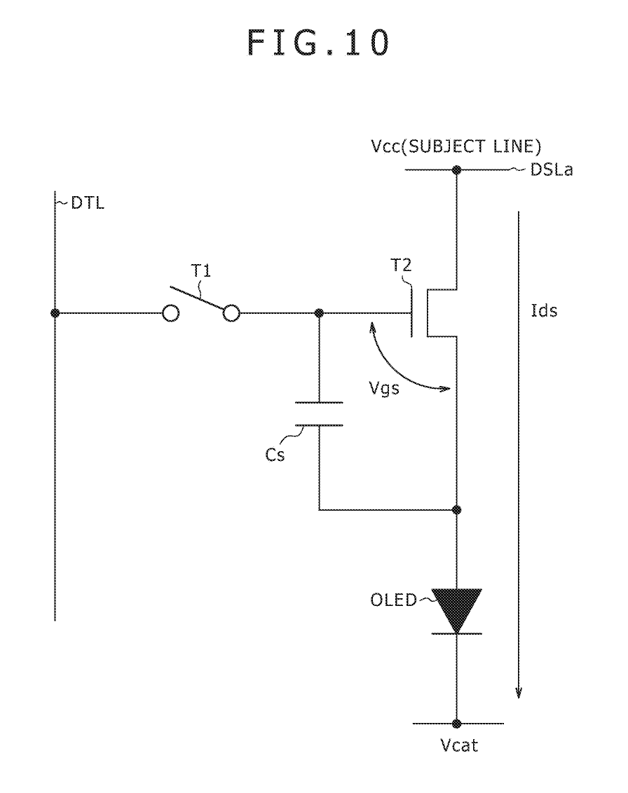

FIG. 10 shows the operation state in the pixel circuit in the light-emission state. In this state, the write transistor T1 is in the off-state. On the other hand, the drive transistor T2 operates in the saturation region and supplies the current Ids dependent upon the gate-source voltage Vgs to the organic EL element OLED (FIGS. 9A to 9E (t1)).

Next, the operation state of the non-light-emission state will be described below. At the start of the non-light-emission state, the potential of the current supply line DSLa is switched from the higher potential Vcc to the lower potential Vss (FIGS. 9A to 9E (t2)). At this time, the light emission of the organic EL element is stopped if the threshold voltage Vthel of the organic EL element satisfies the relationship Vss−Vcath (cathode potential)<Vthel.

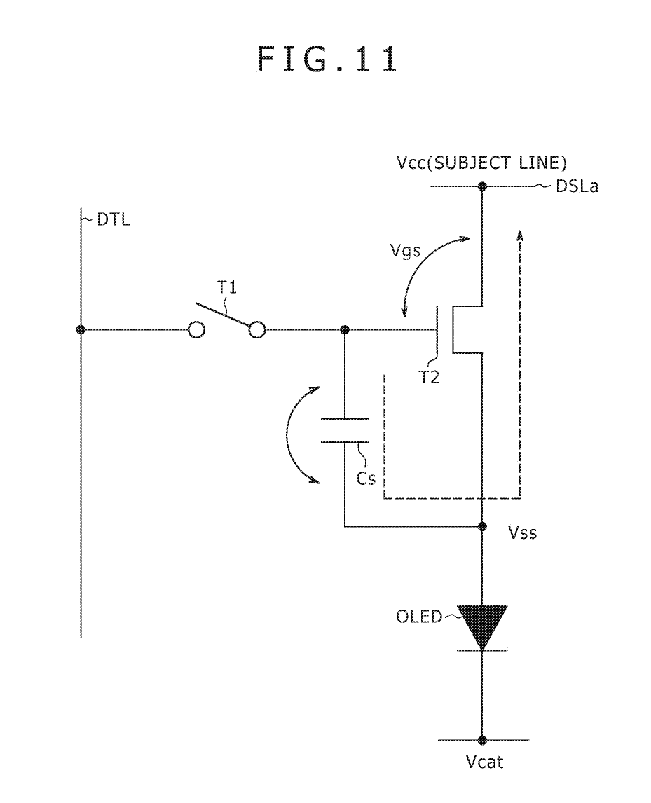

The source potential Vs of the drive transistor T2 becomes the same as the potential of the current supply line DSLa. That is, the anode electrode of the organic EL element is charged to the lower potential Vss. FIG. 11 shows the operation state in the pixel circuit in the period t2. As shown by the dashed line in FIG. 11, the charges held in the hold capacitor Cs are discharged to the current supply line DSLa at this time.

Thereafter, in response to the switch of the write control line WSL to the higher potential after the transition of the potential of the signal line DTL to the offset potential Vofs for threshold correction, the gate potential of the drive transistor T2 is changed to the offset potential Vofs via the turned-on write transistor T1 (FIGS. 9A to 9E (t3)).

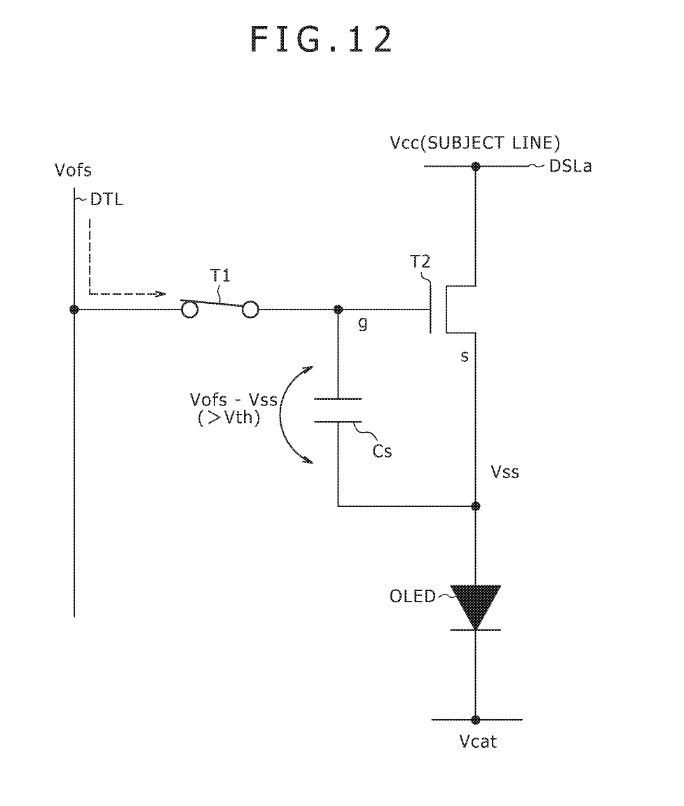

FIG. 12 shows the operation state in the pixel circuit in the period t3. In the period t3, the gate-source voltage Vgs of the drive transistor T2 is expressed as Vofs−Vss. This voltage is set higher than the threshold voltage Vth of the drive transistor T2. This is because threshold correction operation can not be carried out unless the relationship Vofs−Vss>Vth is satisfied.

Subsequently, the potential of the current supply line DSLa is switched to the higher potential Vcc again (FIGS. 9A to 9E (t4)). Due to the switch of the potential of the current supply line DSLa to the higher potential Vcc, the anode potential Vel of the organic EL element OLED becomes the source potential Vs of the drive transistor T2.

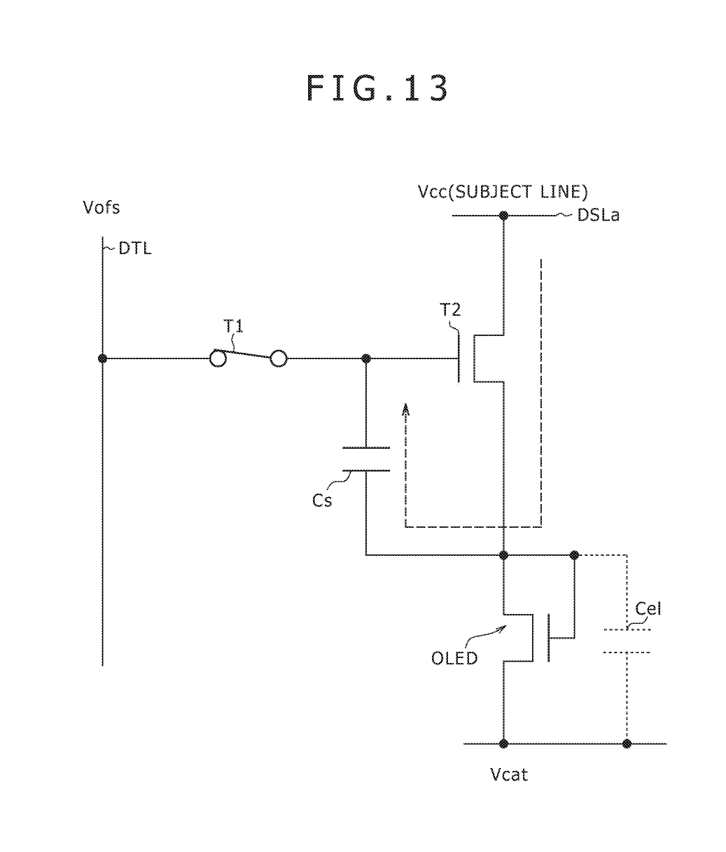

FIG. 13 shows the operation state in the pixel circuit in the period t4. In FIG. 13, the organic EL element OLED is represented by an equivalent circuit. Specifically, it is represented by a diode and a parasitic capacitor Cel. In the period t4, the drive current Ids flowing through the drive transistor T2 is used to charge the hold capacitor Cs and the parasitic capacitor Cel as long as the relationship Vel≦Vcat+Vthel is satisfied (based on the assumption that the leakage current of the organic EL element is considerably smaller than the drive current Ids flowing through the drive transistor T2).

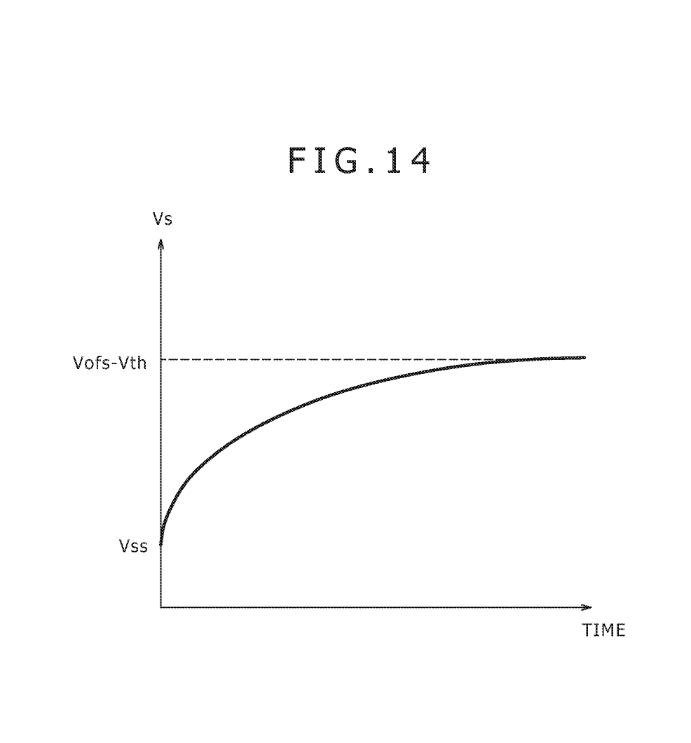

As a result, as shown in FIG. 14, the anode potential Vel of the organic EL element OLED rises up along with time elapse. Specifically, the source potential Vs of the drive transistor T2 starts to rise up, with the gate potential Vg thereof fixed at the offset potential Vofs. This operation is the threshold correction operation.

In due course, the gate-source voltage Vgs of the drive transistor T2 converges on the threshold voltage Vth. At this time, the relationship Vel=Vofs−Vth Vcat+Vthel is satisfied.

Upon the end of the threshold correction period, the write transistor T1 is turned off again (FIGS. 9A to 9E (t5)).

Due to this turning-off, the gate potential Vg of the drive transistor T2 enters the floating state. However, the drive transistor T2 is in the cut-off state because the gate-source voltage Vgs has converged on the threshold voltage Vth, and therefore the drive current Ids does not flow.

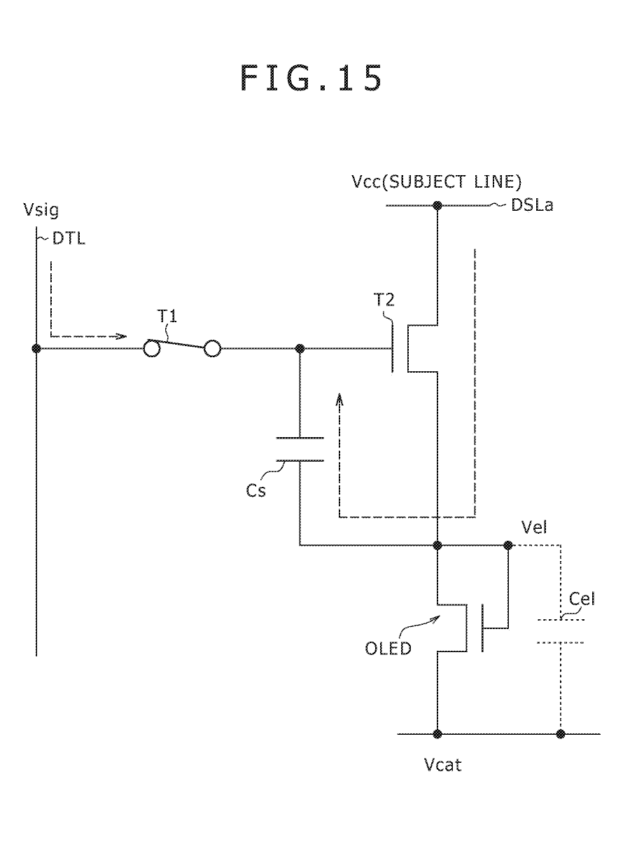

Thereafter, the write transistor T1 is controlled to the on-state again after the timing necessary for the transition of the potential of the signal line DTL to the signal potential Vsig (FIGS. 9A to 9E (t6)). FIG. 15 shows the operation state in the pixel circuit in the period t6. The signal potential Vsig is the potential supplied depending on the grayscale of the corresponding pixel.

In the period t6, the gate potential Vg of the drive transistor T2 shifts to the signal potential Vsig. That is, the gate-source voltage Vgs becomes higher than the threshold voltage Vth. Thus, the drive transistor T2 enters the on-state, so that the drive current Ids starts to flow so as to charge the hold capacitor Cs and the parasitic capacitor Cel.

In response to the start of the supply of the drive current Ids, the source potential Vs of the drive transistor T2 rises up. The drive current Ids supplied by the drive transistor T2 is used to charge the hold capacitor Cs and the parasitic capacitor Cel as long as the source potential Vs of the drive transistor T2 is lower than the sum of the threshold voltage Vthel and the cathode voltage Vcat of the organic EL element (based on the assumption that the leakage current that flows into the organic EL element OLED is considerably smaller than the drive current Ids).

At the start timing of this operation, the threshold correction operation for the drive transistor T2 has been already completed. Therefore, the drive current Ids supplied from the drive transistor T2 has the value reflecting the mobility μ of the drive transistor T2. Specifically, when the drive transistor has higher mobility p, the larger drive current Ids flows and the source potential Vs also rises up more rapidly.

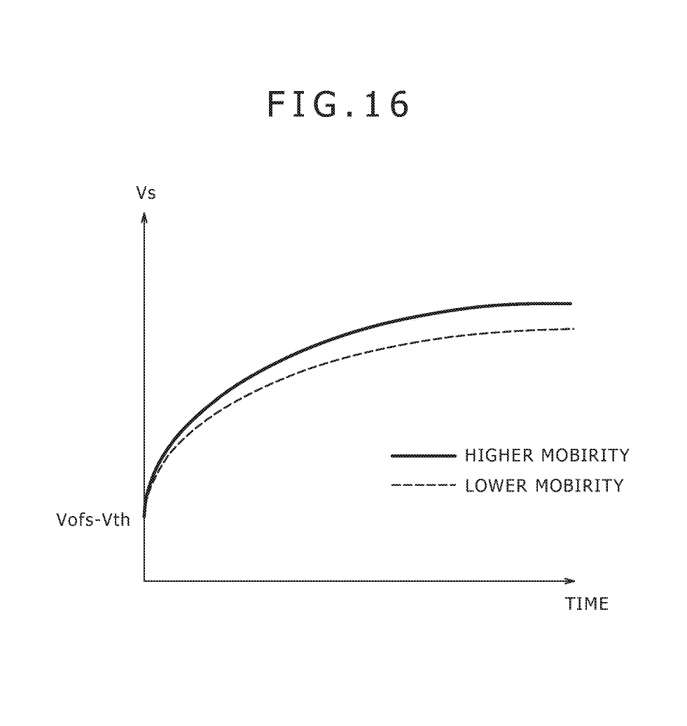

In contrast, when the drive transistor has lower mobility p, the smaller drive current Ids flows and the source potential Vs also rises up more slowly (FIG. 16).

As a result, the voltage held in the hold capacitor Cs is corrected depending on the mobility μ of the drive transistor T2. That is, the gate-source voltage Vgs of the drive transistor T2 is changed to the voltage resulting from the correction of the mobility μ.

At last, the write transistor T1 is turned off, so that the writing of the signal potential Vsig is ended. At this time, the gate-source voltage Vgs (=Vsig−Vofs+Vth−ΔV) of the drive transistor T2 is higher than the threshold voltage Vth. Therefore, the supply of a drive current Ids' is continued and the light emission of the organic EL element OLED starts.

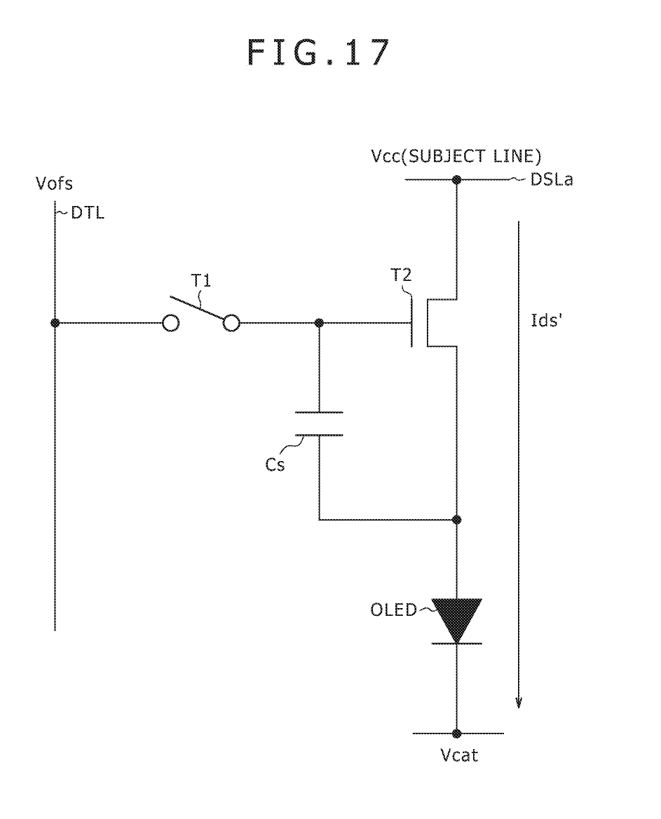

Due to the flowing of the drive current Ids' to the organic EL element OLED, the source potential Vs of the drive transistor T2 rises up to a potential Vx. FIG. 17 shows the operation state in the pixel circuit in the light-emission period.

In the light-emission period, the gate potential Vg of the drive transistor T2 is in the floating state. Therefore, due to bootstrap operation by the hold capacitor Cs, the gate potential Vg of the drive transistor T2 rises up, with the gate-source voltage Vgs kept constant (FIGS. 9A to 9E (t7)).

Also in the drive circuit proposed as the present form example, the I-V characteristic of the organic EL element OLED changes as the total light-emission time becomes longer. That is, the source potential Vs of the drive transistor T2 also changes.

However, no change occurs in the amount of the current that flows through the organic EL element OLED because the gate-source voltage Vgs of the drive transistor T2 is kept constant due to the hold capacitor Cs.

If the pixel circuit and the drive system proposed as the present form example are employed, it is possible to always supply the drive current Ids dependent upon the signal potential Vsig irrespective of change in the I-V characteristic of the organic EL element OLED.

That is, the light-emission luminance can be continuously kept at the luminance dependent upon the signal potential Vsig irrespective of aging change in the characteristics of the organic EL element OLED.

### (B-3) Summary

As above, by employing the pixel circuit and the drive system described for the present form example, an organic EL panel free from variation in the luminance from pixel to pixel can be achieved even when the drive transistor T2 is formed of an N-channel thin film transistor. Furthermore, the pixel circuit can be formed by using only N-channel thin film transistors, which makes it possible to employ an amorphous silicon process for the manufacturing of the organic EL panel.

### (C) Second Form Example

### (C-1) Discussion of Other Technical Problems

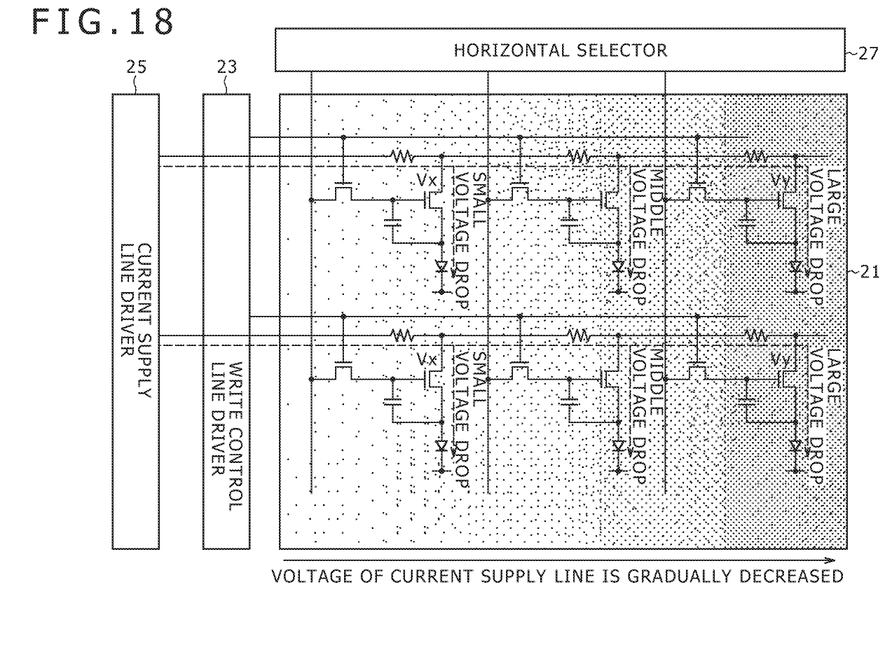

As described above, the organic EL element OLED is a current-driven element. Therefore, the drive current Ids necessary for the respective pixel circuits cumulatively flows through the current supply line DSLa. FIG. 18 shows the relationship between pixel positions and voltage drops when the current supply line DSLa extends in parallel to the horizontal lines. In FIG. 18, the resistive component of the current supply line DSLa is expressly shown.

Due to the influence of the resistive component shown in FIG. 18, the amount of the voltage drop in the current supply line DSLa becomes larger gradually as the pixel position becomes farther from the current supply line driver 25. This is because the voltage drop per one pixel is represented as the product of the drive current Ids corresponding to the pixel circuit and the interconnect resistance per one pixel. Naturally, a supply potential Vy of the pixel circuit at the right end of the screen is lower than a supply potential Vx of the pixel circuit at the left end of the screen.

This supply potential lowering acts to decrease the drain-source voltage Vds of the drive transistor T2 included in the pixel circuit.

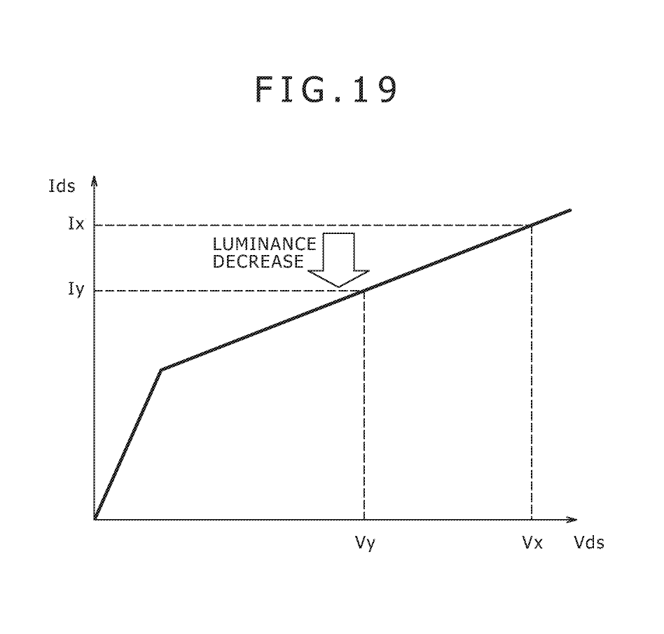

FIG. 19 shows the influence on the drive current Ids due to the difference in the supply potential between the right end and the left end of the screen. As shown in FIG. 19, even if the grayscale is the same, difference in the light-emission luminance arises if the drive current Ids is different. This phenomenon is perceived as the shading phenomenon.

This phenomenon called shading is attributed to the interconnect structure of the current supply line DSLa as described above. Therefore, it is impossible for the functions to correct the characteristics of the drive transistor T2, described for the first form example, to prevent the occurrence of the shading phenomenon.

In addition, the shading phenomenon also relates to the occurrence of crosstalk.

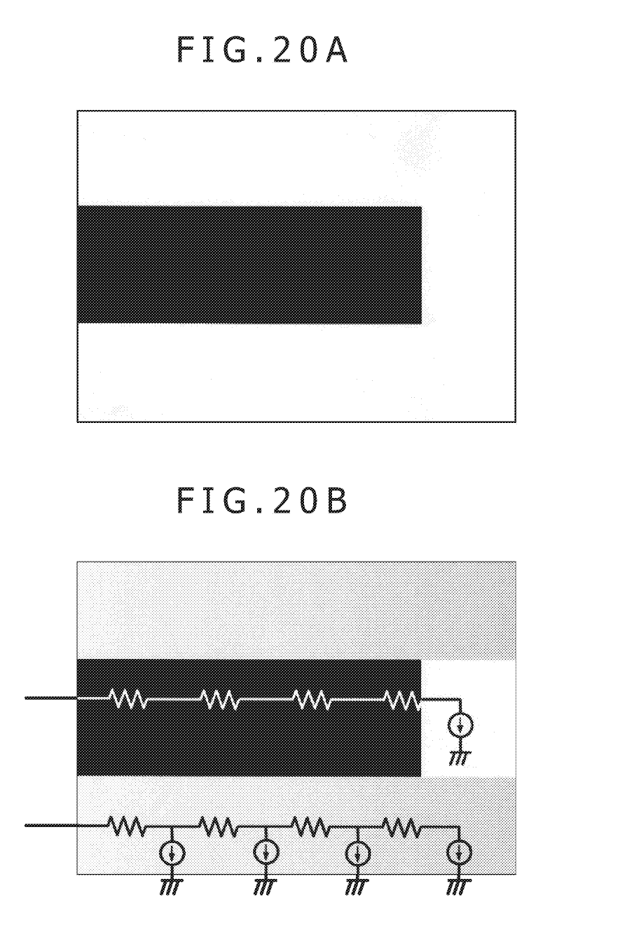

The crosstalk refers to a phenomenon in which, when an image like that shown in FIG. 20A (such as an image in which a black-displayed window is disposed in a partial area of an all-white-background image) is displayed, luminance difference among the horizontal lines is perceived as shown in FIG. 20B. Specifically, the luminance difference arises between the background-white part on the same horizontal line as that of the black-displayed window and the background-white parts on the horizontal lines on the upper and lower sides of the black-displayed window.

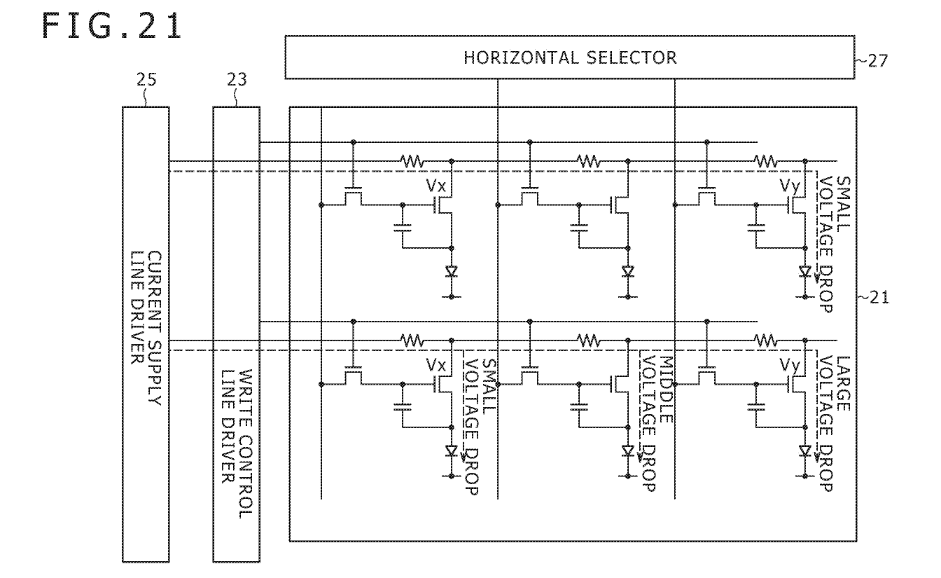

This luminance difference is attributed to the state in which no drive current Ids flows in the pixel circuits corresponding to the black-displayed window part as shown in FIG. 21. Specifically, this luminance difference is attributed to the state in which the voltage drop in the current supply line DSL in the black-displayed window part is very small. As a result, the voltage drop in the current supply line DSL near the screen right end on the same row as that of the black-displayed window part is very small, and thus high light-emission luminance is obtained.

On the other hand, near the screen right end on a horizontal line different from that of the black-displayed window, the voltage drop amount is large due to the accumulation of the voltage drops as shown in FIG. 21. That is, the light-emission luminance is lowered corresponding to the drop of the supply potential. As a result, even on the same right-end column, luminance difference arises between the horizontal line of the black-displayed window and other horizontal lines, and luminance difference larger than a certain amount is visually recognized.

The voltage drop amount is obtained as the sum of the products of the drive current and the interconnect resistance of the current supply line.

For example, in the case of the panel structure of FIG. 21, when the number of pixels (including all of R pixels, G pixels, and B pixels) on the horizontal line is defined as N, the maximum value of the drive current Ids necessary for the respective pixels is defined as I, and the interconnect resistance per one pixel is defined as r, a voltage drop amount Vy of the current supply line DSL at the remotest position from the current supply line driver 25 (in the present form example, at the screen right end) is represented by the following equation.

Vy={N(N+1)/2}×I×r (Equation 1)

Therefore, the voltage drop amount can be decreased if at least one of N, I, and r is decreased.

In the following, a discussion will be made on the scheme of decreasing the interconnect resistance r. To decrease the interconnect resistance r, it is necessary to increase the interconnect width of the current supply line DSL or increase the thickness of the metal film (e.g. aluminum film) of the current supply line DSL.

Of these methods, the method of increasing the thickness involves change of the process, which possibly causes the lowering of the production takt and the yield, and so on. Therefore, the other method should be selected. Specifically, the method of increasing the line width of the current supply line DSL should be selected.

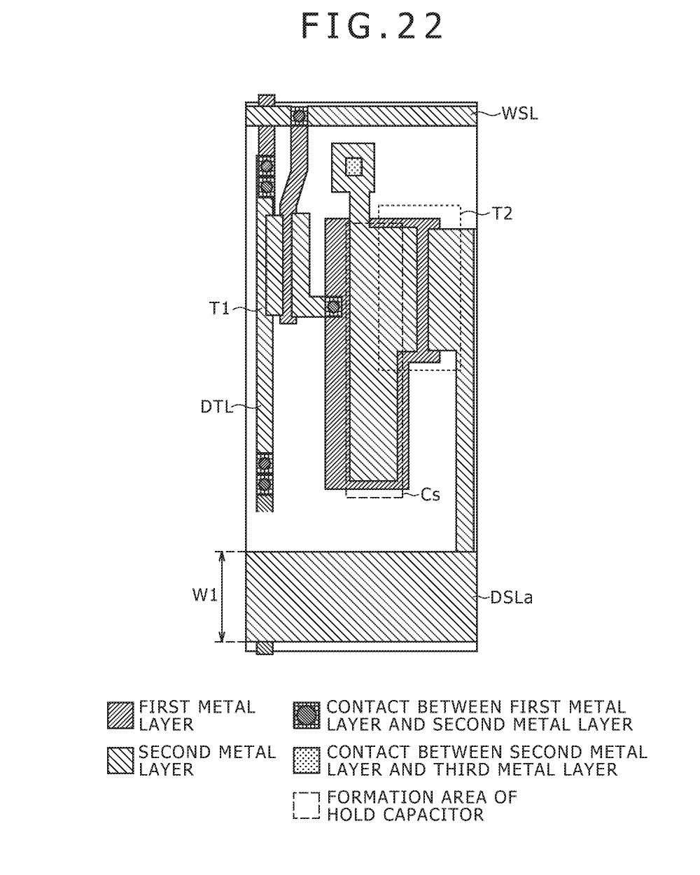

FIG. 22 shows a layout example of the pixel circuit 31 corresponding to the first form example. The same symbol in FIG. 22 as that in FIG. 8 indicates the same component. In FIG. 22, the line width of the current supply line DSLa is represented as W1.

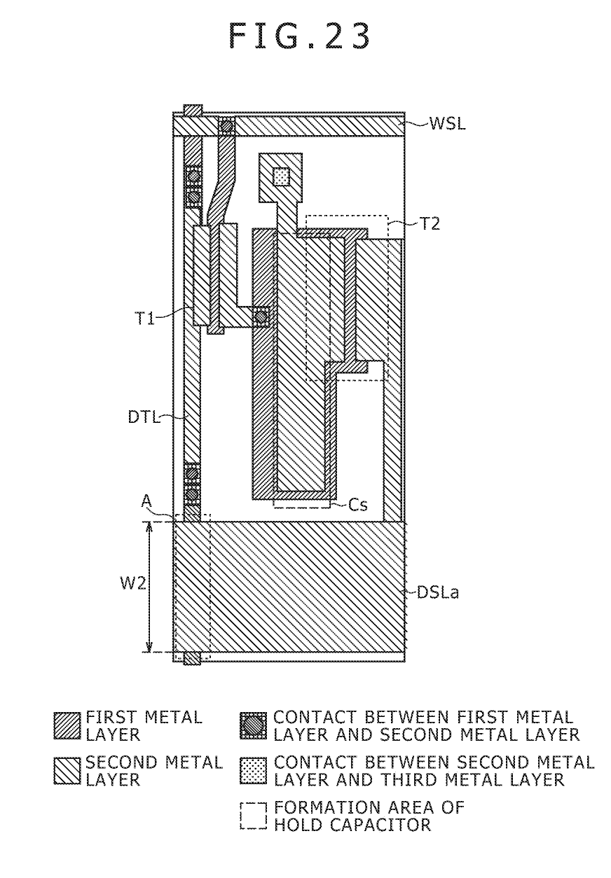

FIG. 23 shows a layout example in which the line width of the current supply line DSLa is increased to W2 (>W1). If the layout of FIG. 23 is employed, the interconnect resistance of the current supply line DSLa can be decreased. As a result, suppression of shading and crosstalk can be expected.

However, due to the increase in the line width of the current supply line DSLa, the area of the intersection part between the current supply line DSLa and the signal line DTL (the part surrounded by the dashed line and given symbol A in FIG. 23) is increased.

This area increase leads to increase in the inter-line capacitance (coupling capacitance) formed between the current supply line DSLa and the signal line DTL. That is, the area increase causes another technical problem that potential change of the current supply line DSLa is easily transmitted to the signal line DTL.

For example, at the timing of writing of the signal potential Vsig in the pixel circuit corresponding to a certain horizontal line, the potential of the current supply line DSLa corresponding to another horizontal line possibly changes. In this case, the mobility correction for the drive transistor T2 will be incorrectly carried out unless the potential changes of the gate and the source of the drive transistor T2 due to the potential change of the current supply line DSLa are cancelled within the mobility correction period.

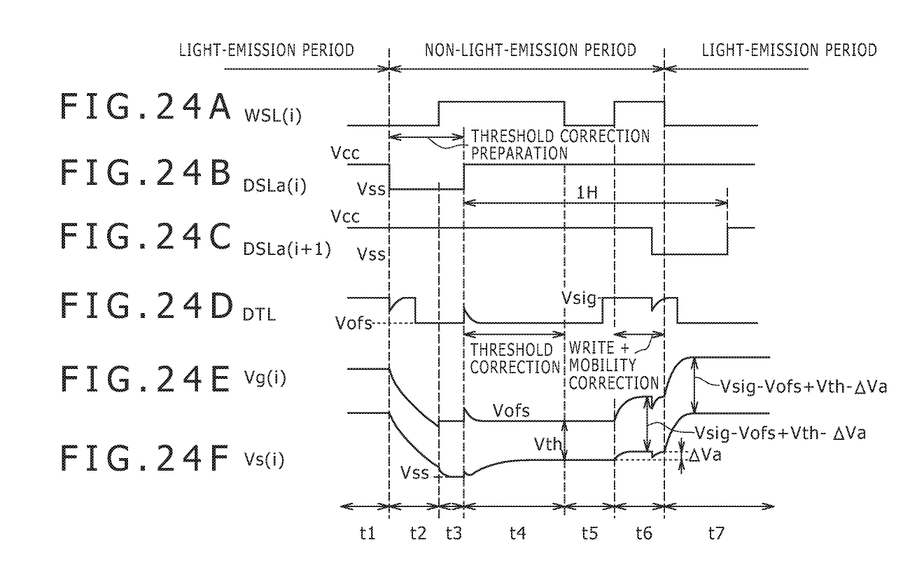

FIGS. 24A to 24F show drive operation examples of the pixel circuit 31 corresponding to a certain horizontal line. The position of the horizontal line of interest is represented by a suffix “i.” The suffix “i” indicates the horizontal line on the i-th row from the uppermost row on the screen.

FIG. 24A shows a signal waveform example of the write control line WSL(i) of the pixel circuit 31 corresponding to the i-th horizontal line. FIG. 24B shows a signal waveform example of the current supply line DSLa(i) corresponding to the i-th horizontal line. FIG. 24C shows a signal waveform example of the current supply line DSLa(i+1) corresponding to the I+1-th horizontal line.

FIG. 24D shows the signal waveform of the signal line DTL that intersects with the current supply lines. FIG. 24E shows the signal waveform of the gate potential Vg of the drive transistor T2 included in the pixel circuit 31 corresponding to the i-th horizontal line. FIG. 24F shows the signal waveform of the source potential Vs of the drive transistor T2 included in the pixel circuit 31 corresponding to the i-th horizontal line.

As shown in FIG. 24D, potential change of the current supply line DSLa is transmitted to the signal line DTL(i) via the interconnect capacitance of the intersection part irrespective whether this potential change occurred on the same row as that of the pixel circuit as the mobility correction target or occurred on another row. From FIGS. 24A to 24F, a phenomenon can be found in which change in the supply potential (change from the higher potential Vcc to the lower potential Vss) in the period of writing of the signal potential Vsig and mobility correction (t6) affects the gate potential Vg and the source potential Vs of the drive transistor T2.

Nevertheless, if the gate potential Vg and the source potential Vs return to the original potentials in the mobility correction period, the mobility correction operation can be completed without any problem. However, unless these potentials return to the original potentials, the mobility correction operation can not be correctly completed.

This is because the potential change amount of the source potential Vs is smaller than that of the gate potential Vg due to the intermediary of the hold capacitor Cs.

Specifically, unless the change in the gate potential Vg is cancelled in the mobility correction period, the gate-source voltage Vgs of the drive transistor T2 becomes lower than that obtained through normal mobility correction. This means that the screen luminance becomes lower than the original luminance level.

In addition, the amount of the potential change due to the influence of the coupling is constant irrespective of the signal potential Vsig.

Therefore, when the signal potential Vsig has a value for low luminance, the lowering of the luminance level has serious influence. This causes image quality lowering as erroneous expression of lower-side grayscales as 100% black and insufficiency in gamma correction.

In addition, the transmission of potential change to the signal line DTL often affects the pixel circuit driving when the threshold correction period is divided into plural periods in plural horizontal scanning periods.

For example, in the threshold correction period for the pixel circuit corresponding to a certain horizontal line, the potential of the current supply line DSLa corresponding to another horizontal line possibly changes. In this case, the threshold correction for the drive transistor T2 will be incorrectly carried out unless the potential changes of the gate and the source of the drive transistor T2 due to the potential change of the current supply line DSLa are cancelled within the threshold correction period.

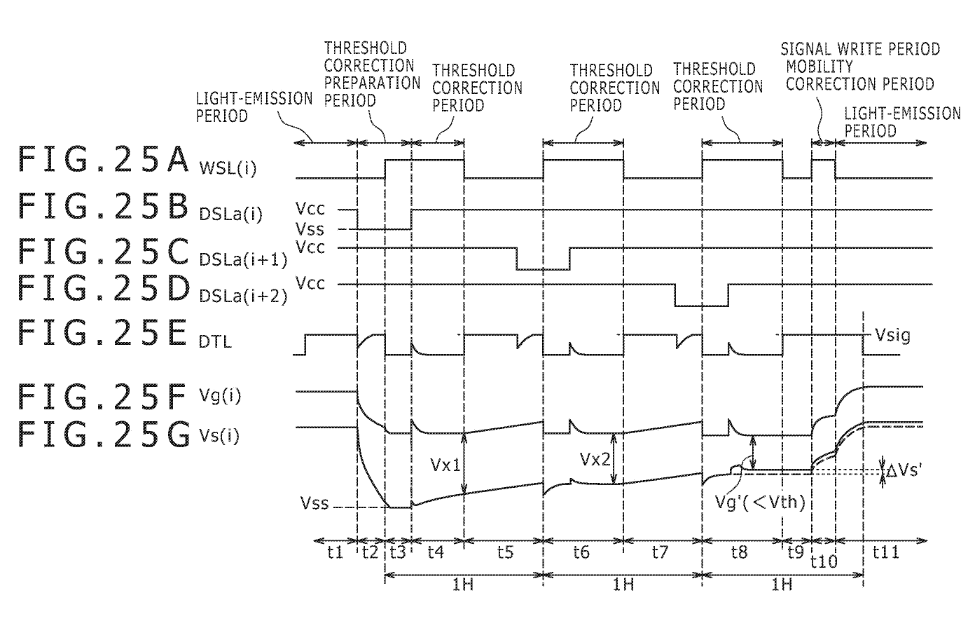

FIGS. 25A to 25G show drive operation examples of the pixel circuit 31 corresponding to a certain horizontal line. Specifically, FIGS. 25A to 25G show an operation example in which threshold correction operation is executed in three horizontal scanning periods in a divided manner. Also in FIGS. 25A to 25G, the position of the horizontal line of interest is represented by a suffix “i.” The suffix “i” indicates the horizontal line on the i-th row from the uppermost row on the screen.

FIG. 25A shows a signal waveform example of the write control line WSL(i) of the pixel circuit 31 corresponding to the i-th horizontal line. FIG. 25B shows a signal waveform example of the current supply line DSLa(i) corresponding to the i-th horizontal line. FIG. 25C shows a signal waveform example of the current supply line DSLa(I+1) corresponding to the I+1-th horizontal line.

FIG. 25D shows a signal waveform example of the current supply line DSLa(I+2) corresponding to the I+2-th horizontal line.

FIG. 25E shows the signal waveform of the signal line DTL that intersects with the current supply lines. FIG. 25F shows the signal waveform of the gate potential Vg of the drive transistor T2 included in the pixel circuit 31 corresponding to the i-th horizontal line. FIG. 25G shows the signal waveform of the source potential Vs of the drive transistor T2 included in the pixel circuit 31 corresponding to the i-th horizontal line.

As shown in FIG. 25E, potential change of the current supply line DSLa is transmitted to the signal line DTL via the interconnect capacitance of the intersection part irrespective whether this potential change occurred on the same row as that of the pixel circuit as the threshold correction target or occurred on another row. In the case of FIGS. 25A to 25G, changes in the supply potential (changes from the lower potential Vss to the higher potential Vcc) in the periods t3, t4, t6, and t8, during which the write transistor T1 is in the on-state, are transmitted to the gate potential Vg and the source potential Vs of the drive transistor T2.

Also in this case, if the potential changes of the gate potential Vg and the source potential Vs are cancelled in the threshold correction period, the threshold correction can be completed without any problem. However, if potential change of the current supply line DSLa on a different row is transmitted immediately before the end of the threshold correction operation and thus the gate potential Vg and the source potential Vs are changed but not returned to the original potentials, the threshold correction operation can also not be correctly completed.

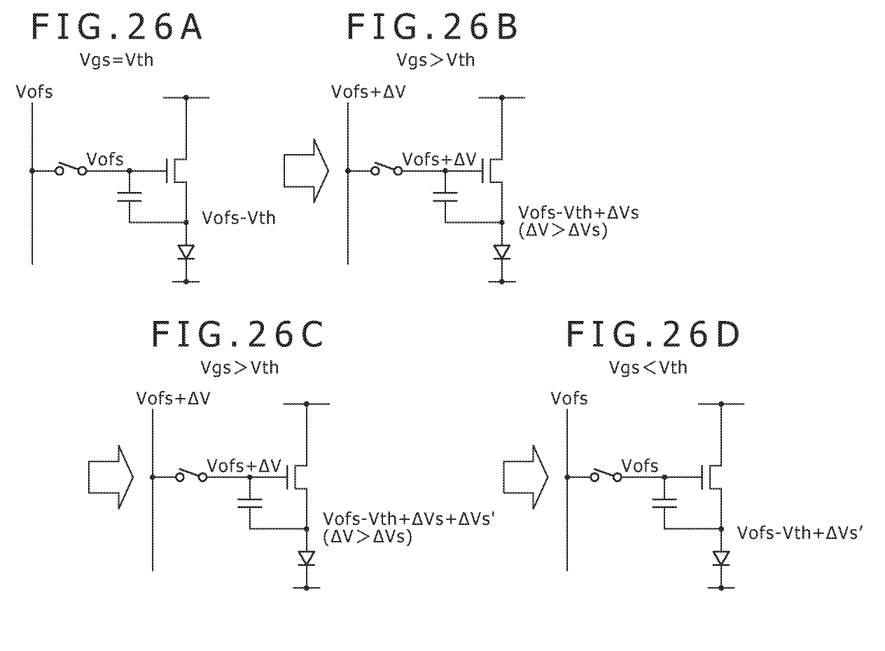

The reason for this is shown in FIGS. 26A to 26D. FIG. 26A shows the potential relationship in the pixel circuit before the occurrence of potential change of the current supply line DSLa. In the case of FIG. 26A, the gate-source voltage Vgs of the drive transistor T2 has already converged on the threshold voltage Vth. FIG. 26B shows the state after the potential of the current supply line DSLa is changed immediately before the end of the threshold correction period.

The gate potential Vg at this time is higher than the offset potential Vofs by ΔV corresponding to the potential change. On the other hand, the change amount ΔVs of the source potential Vs is smaller than the change amount ΔV of the gate potential Vg because the potential change is transmitted to the source via the hold capacitor Cs. Consequently, the gate-source voltage Vgs of the drive transistor T2 becomes higher than the threshold voltage Vth, and thus the drive transistor T2 is turned on again.

As a result, as shown in FIG. 26C, the mobility correction operation for the drive transistor T2 continues, so that the source potential Vs further rises up by ΔVs′.

In due course, as shown in FIG. 26D, when the influence of the potential change of the current supply line DSLa disappears, the gate potential Vg of the drive transistor T2 converges on the offset potential Vofs and the source potential Vs converges on the potential higher by ΔVs' than the potential before the potential change.

This means that the gate-source voltage Vgs of the drive transistor T2 has been changed to a voltage Vgs' lower than the threshold voltage Vth at the end timing of the threshold correction period.

That is, the threshold correction operation is not normally carried out. As a result, the light-emission luminance does not corresponds with the original luminance.

In addition, the increase in the intersection area between the current supply line DSLa and the signal line DTL means increase in the overlapping area between the metal layers. Therefore, the increase in the intersection area also causes increase in the possibility of short-circuit of the layers.

Furthermore, as shown in FIG. 23, if the current supply line DSLa is formed as a layer (second layer) above the signal line DTL, the interconnect length of the layer part of the signal line DTL (first layer) under the current supply line DSLa is large. In this case, if the interconnect resistance of the under layer (first layer) part is higher than that of the upper layer (second layer), the interconnect resistance of the signal line DTL as a whole is high.

### (C-2) Layout by Proposal

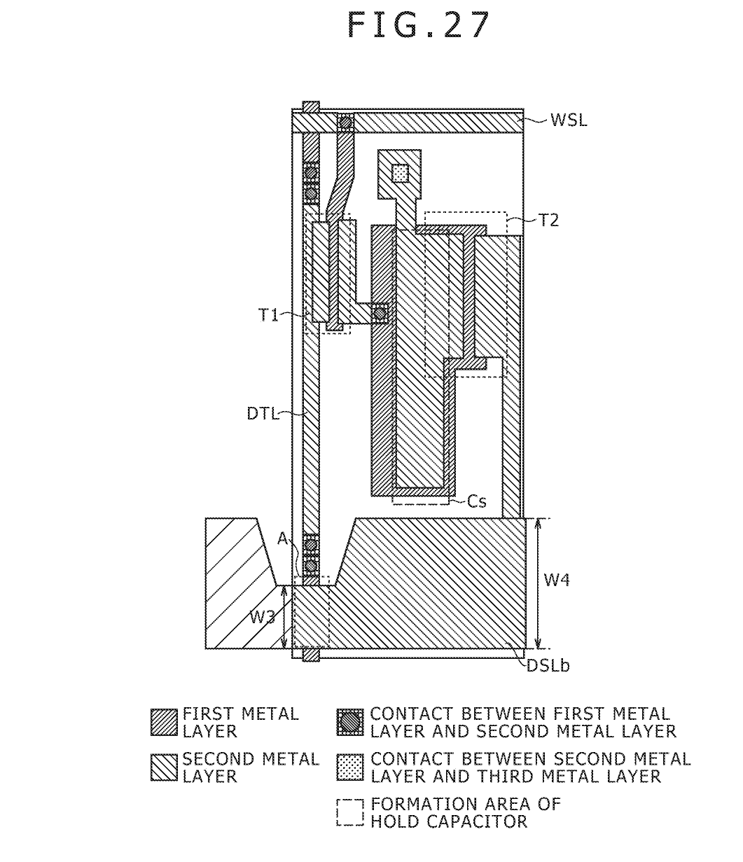

To address these problems, the present inventors propose a layout shown in FIG. 27. Specifically, in the interconnect structure of this layout, only the intersection part of a current supply line DSLb with the signal line DTL has a small line width W3 (<W1), whereas the other part of the current supply line DSLb has a large line width W4 (>W1).

Therefore, the small-width part and the large-width part of the current supply line DSLb alternately exist along the horizontal line with a cycle of the pixel pitch.

In the case of FIG. 27, the line width of the current supply line DSLb is gradually increased from the line width W3 to the line width W4 along the horizontal direction, and is gradually decreased from the line width W4 to the line width W3 along the horizontal direction.

Alternatively, the line width of the current supply line DSLb may be changed in a stepwise manner (with right-angle corners) between the line widths W3 and W4.

Using this interconnect structure can decrease the interconnect resistance of the current supply line DSLb as a whole and thus can effectively suppress the occurrence of shading and crosstalk.

The line widths W3 and W4 (particularly, W4) are so designed that the voltage drop amount Vy represented by Equation 1 is smaller than the limit value relating to visual recognition of crosstalk. The limit value relating to visual recognition of crosstalk differs depending on the use environment, the horizontal scanning cycle, and so on. As a measure of the limit value, e.g. 1% of the luminance corresponding to the highest grayscale is available.

Furthermore, the interconnect structure shown in FIG. 27 can solve the above-described other problems.

First, in the interconnect structure shown in FIG. 27, the inter-line capacitance formed between the current supply line DSLb and the signal line DTL is low. This is because the line width of the intersection part is decreased to W3. Therefore, transmission of potential change of the current supply line DSLb to the signal line DTL can be reduced.

Consequently, even if the potential of the current supply line DSLb corresponding to another horizontal line changes at the timing of writing of the signal potential Vsig in the pixel circuit corresponding to a certain horizontal line and thus potential change occurs in the signal potential Vsig that is being written, the potential change can be cancelled in the mobility correction period because the change itself is small. That is, normal mobility correction can be ensured.

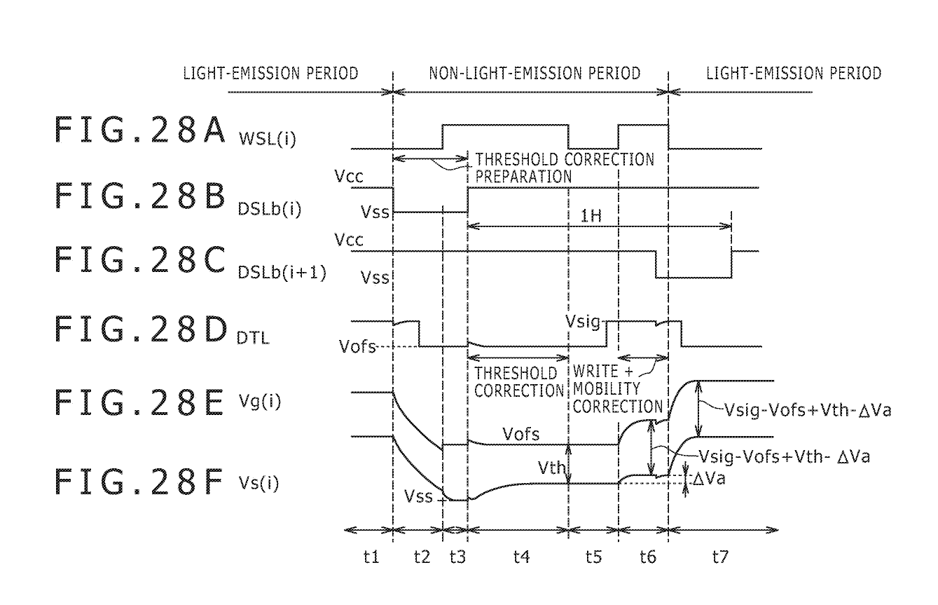

FIGS. 28A to 28F show a drive operation example of the pixel circuit 31 corresponding to a certain horizontal line. FIGS. 28A to 28F are diagram corresponding to FIGS. 24A to 24F, and the position of the horizontal line of interest is represented by a suffix “i.” Therefore, the signal waveforms of FIGS. 28A to 28F correspond to the signal waveforms of FIGS. 24A to 24F, respectively.

Naturally, also in the interconnect structure proposed by the present inventors, potential change of the current supply line DSLb is transmitted to the signal line DTL via the inter-line capacitance formed at the intersection part with the signal line DTL as shown in FIG. 28D. However, the transmission amount is smaller than that in FIGS. 24A to 24F.

Therefore, although the supply potential is changed from the higher potential Vcc to the lower potential Vss in the period of the writing of the signal potential Vsig and the mobility correction (t6), the amounts of changes occurring in the gate potential Vg and the source potential Vs of the drive transistor T2 are small.

Thus, the gate potential Vg and the source potential Vs can be returned to the original potentials in the mobility correction period surely, and hence the mobility correction operation can be completed within the period. Therefore, not only when the signal potential Vsig has a value for high luminance but also when it has a value for low luminance, the original light-emission luminance corresponding to the grayscale can be achieved.

In addition, the suppression of the amount of potential change transmitted to the signal line DTL offers advantageous effects also when the threshold correction period is divided into plural periods in plural horizontal scanning periods.

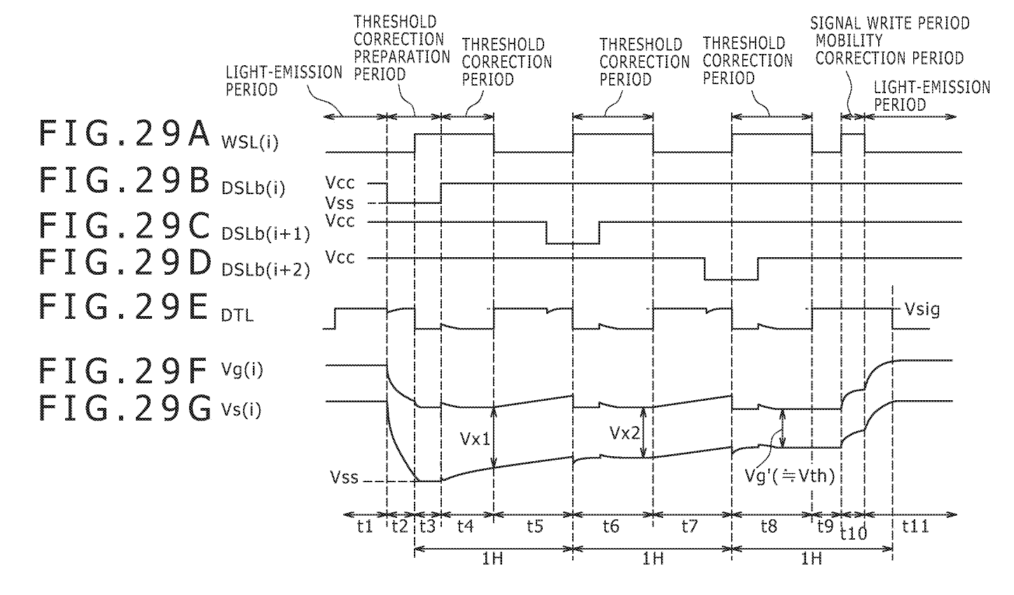

This feature will be described below with reference to FIGS. 29A to 29G. FIGS. 29A to 29G are diagram corresponding to FIGS. 25A to 25G, and the position of the horizontal line of interest is represented by a suffix “i.” Therefore, the signal waveforms of FIGS. 29A to 29G correspond to the signal waveforms of FIGS. 25A to 25G, respectively.

Also in the case of FIGS. 29A to 29G, potential changes of the current supply line DSLb (changes from the lower potential Vss to the higher potential Vcc) in the periods t3, t4, t6, and t8, during which the write transistor T1 is in the on-state, are transmitted to the gate potential Vg and the source potential Vs of the drive transistor T2.

However, the amounts of the transmission of the potential changes are very small because the inter-line capacitance (coupling capacitance) formed at the intersection part between the current supply line DSLb and the signal line DTL based on the interconnect structure proposed by the present inventors is low.

As a result, even if potential changes of the gate potential Vg and the source potential Vs occur immediately before the end of the threshold correction period, the changes can be cancelled in the remaining correction period, so that the threshold correction can be completed without any problem. Furthermore, even if potential change is transmitted after the completion of the threshold correction operation and the threshold correction operation is restarted, the amount AVs' of increase in the source potential Vs occurring at this time is so small as to be ignorable. Therefore, there is no need to consider the influence on the threshold correction operation.

In addition, in the interconnect structure shown in FIG. 27, the intersection area of the current supply line DSLb and the signal line DTL is small and thus the overlapping area of the metal layers is also small. Therefore, an effect of decreasing the possibility of short-circuit of the layers can also be expected.

Furthermore, as shown in FIG. 27, if the current supply line DSLb is formed as a layer (second layer) above the signal line DTL, the interconnect length of the layer part of the signal line DTL (first layer) under the current supply line DSLb can be decreased.

Therefore, even if the interconnect resistance of the under layer (first layer) part is higher than that of the upper layer (second layer), the interconnect resistance of the signal line DTL as a whole can be decreased.

The above-described various advantageous effects are particularly large when the organic EL panel has a top-emission pixel structure.

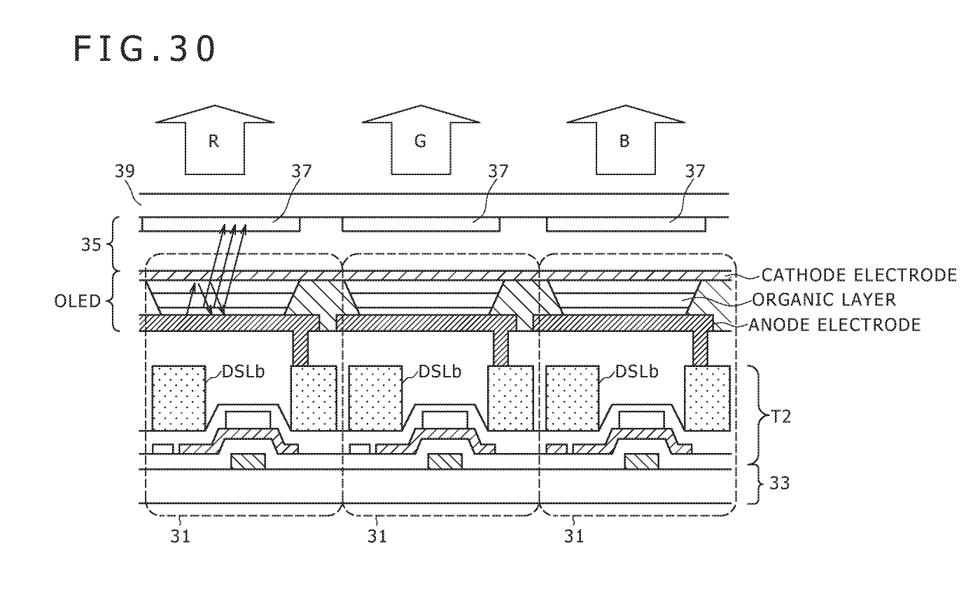

FIG. 30 shows a sectional structural example of an organic EL panel having a top-emission structure. In this structure, the respective elements such as the write transistor T1, the drive transistor T2, and the hold capacitor Cs are formed over a glass substrate 33 as a support substrate, and the organic EL elements OLED are formed over these elements.

Over the organic EL elements OLED, a sealing material 35, color filters 37, and a glass substrate 39 are sequentially disposed.

In this layer structure, light output from an organic layer sequentially passes through the cathode electrode formed of a semi-transparent film and the color filter 37 so as to be output to the external from the surface of the glass substrate 39, which seals these components.

In the top-emission structure, interconnect layers such as the current supply line DSLb and the signal line DTL are not disposed on the optical path. Specifically, the current supply line DSLb is disposed at a layer level lower than that of the organic EL elements OLED.

Therefore, in terms of ensuring of a high aperture ratio, there is no limit to the increase of the line width W4 of the current supply line DSLb at the part other than the intersection part with the signal line DTL, and thus the line width W4 can be increased to the necessary width.

### (C-3) System Configuration

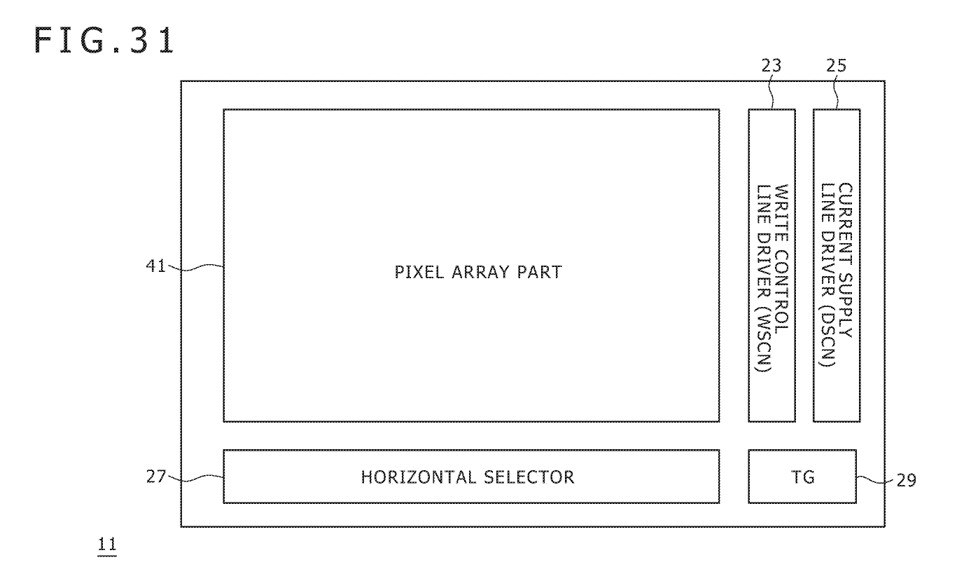

FIG. 31 shows a system configuration example of an organic EL panel 11 having the above-described interconnect structure. The same unit in FIG. 31 as that in FIG. 6 is given the same numeral.

The organic EL panel 11 shown in FIG. 31 includes a pixel array part 41, and the write control line driver 23, the current supply line driver 25, the horizontal selector 27, and the timing generator 29 as drive circuits for the pixel array part 41.

Of these units, the pixel array part 41 has the same structure as that of the pixel array part 21 described for the first form example except for the current supply line DSLb (FIG. 27). Specifically, the pixel array part 41 has a pixel structure in compatible with an active-matrix drive system for controlling the operation state of the pixel circuit based on driving of the current supply line DSLb with potentials of binary values.

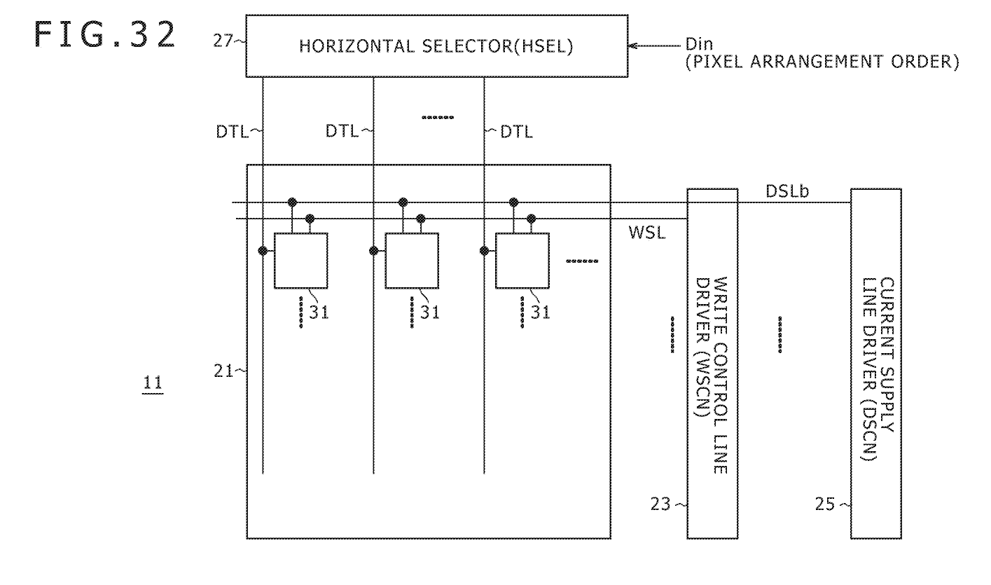

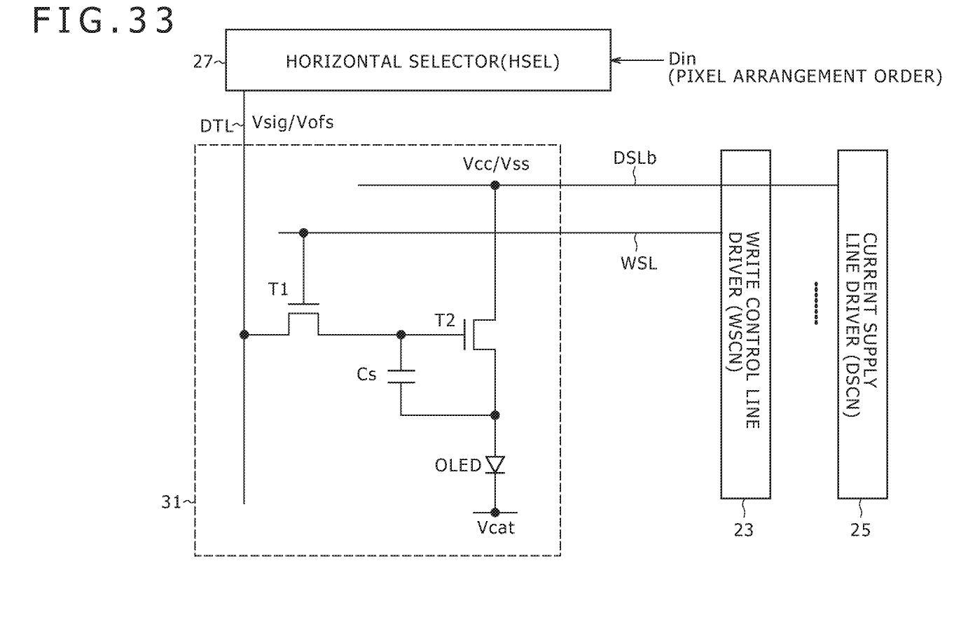

Therefore, the connection relationship between the pixel circuits 31 and the respective drive circuits (FIG. 32) and the internal configuration of the pixel circuit 31 (FIG. 33) are the same as those in the first form example.

### (D) Other Form Examples

### (D-1) Drive System 1

In the above-described form examples, driving of the current supply line DSLb is controlled with potentials of binary values (the higher potential Vcc and the lower potential Vss).

However, it is obvious that the above-described interconnect structure can also be applied to a configuration in which driving of the current supply line DSLb is controlled with potentials of ternary values or more values. If the current supply line DSLb based on the above-described interconnect structure is used, transmission of potential change to the signal line DTL can be effectively suppressed also when driving of the current supply line DSLb is controlled with potentials of ternary values or more values.

### (D-2) Drive System 2

In the above-described form examples, driving of the current supply line DSLb is controlled with potentials of binary values (the higher potential Vcc and the lower potential Vss).

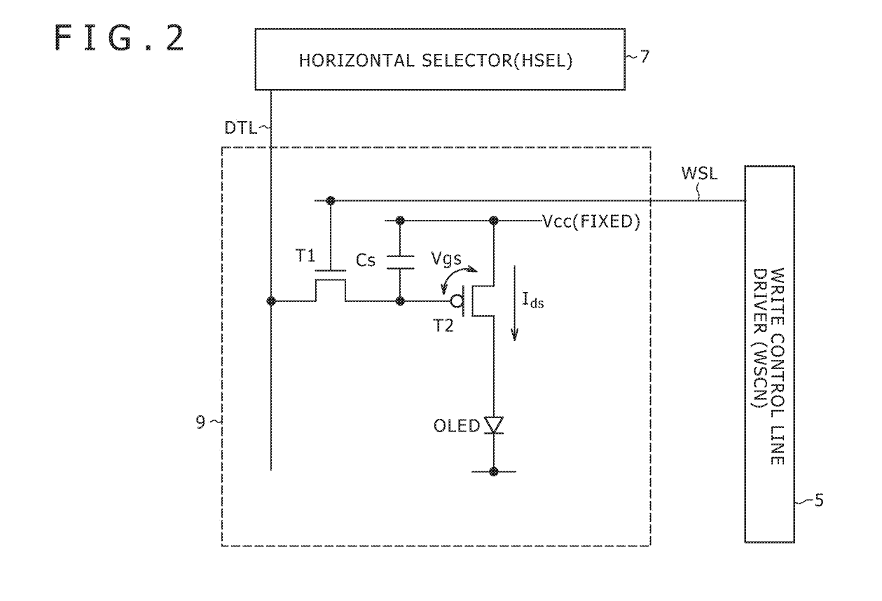

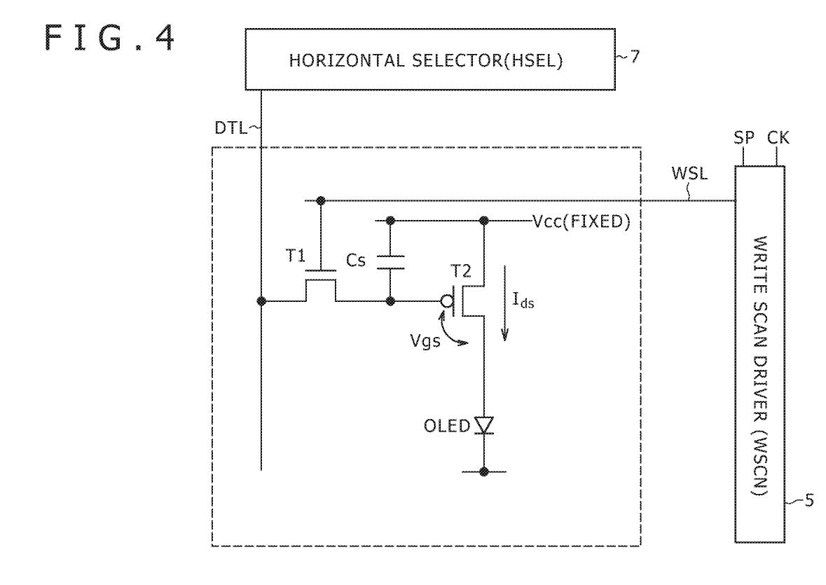

However, the current supply line DSLb can also be employed for e.g. the pixel structures shown in FIGS. 2 and 4. Specifically, the above-described interconnect structure can also be applied to a structure in which the current supply line DSLb is controlled to a fixed potential.

Also in this case, the interconnect resistance of the current supply line DSLb can be decreased, and thus the influence of shading and crosstalk can be reduced.

Furthermore, the area of the intersection part with the signal line DTL can be decreased, which can reduce the inter-line capacitance (coupling capacitance), the resistance of the signal line DTL, and so on.

### (D-3) Drive System 3

In the above-described form examples, the timing of potential change of the current supply line DSLb corresponding to another horizontal line overlaps with the period of writing of the signal line potential (the signal potential Vsig or the offset potential Vofs) on a certain horizontal line.

However, this is not the essential drive condition, but the above-described interconnect structure is effective for suppressing shading and crosstalk even if the timing of potential change of the current supply line DSLb corresponding to another horizontal line does not overlap with the period of writing of the signal potential Vsig or the offset potential Vofs on a certain horizontal line.

### (D-4) Drive System 4

In the above-described form examples, mobility correction is simultaneously executed in the period of writing of the signal potential Vsig.

However, the current supply line DSLb can also be applied to the case in which the writing of the signal potential Vsig and the mobility correction are carried out separately from each other.

### (D-5) Drive System 5

In the above-described form examples, the current supply line driver 25 drives the current supply line DSLb from one side of the pixel array part 41.

However, the above-described interconnect structure can also be applied to the case in which one current supply line DSLb is driven from both the sides of the pixel array part 41.

In this case, the number of pixels driven by one current supply line driver 25 is half that when the current supply line DSLb is driven from one side.

Therefore, through calculation of the equation obtained by replacing the number of pixels N in Equation 1 by N/2, the voltage drop amount near the screen center can be obtained.

In this case, the line widths W3 and W4 are so designed as to provide such a resistance r per one pixel that the obtained voltage drop amount is not perceived as luminance difference.

### (D-6) Pixel Structure 1

In the above-described form examples, the current supply line DSLb is applied to a top-emission pixel structure and therefore is particularly useful because there is no limit to the interconnect width.

However, the pixel structure is not necessarily limited to the top-emission structure but the current supply line DSLb can also be applied to a bottom-emission structure.

### (D-7) Pixel Structure 2

In the above-described form examples, the pixel circuit includes two thin film transistors and the hold capacitor Cs.

However, the current supply line DSLb can also be applied to the pixel circuit including three or more thin film transistors. For example, the signal line DTL may be used exclusively for application of the signal potential Vsig, and an additional thin film transistor may be separately provided for application of the offset potential Vofs.

### (D-8) Product Examples

### (a) Electronic Apparatus

The above description has dealt with an organic EL panel as an example of an embodiment of the present invention. However, the above-described organic EL panel is also distributed in a commercial product form of being mounted to various kinds of electronic apparatus. Examples of products obtained by mounting the organic EL panel on electronic apparatus will be described below.

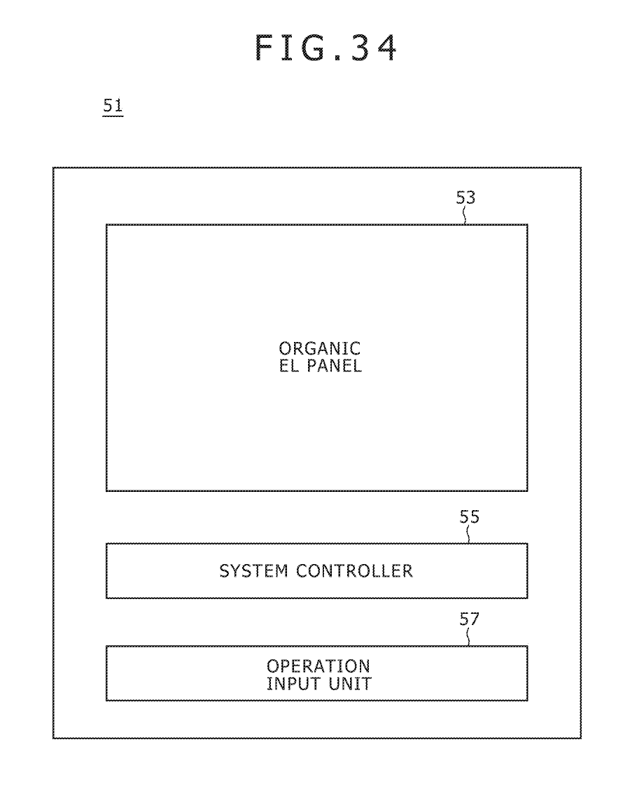

FIG. 34 shows a conceptual configuration example of electronic apparatus 51. The electronic apparatus 51 is composed of an organic EL panel 53, a system controller 55, and an operation input unit 57. As the organic EL panel 53, e.g. the organic EL panel 11 described for the second form example is used.

The details of processing executed by the system controller 55 differ depending on the commercial product form of the electronic apparatus 51. The operation input unit 57 is a device that accepts operation inputs to the system controller 55. As the operation input unit 57, e.g. a mechanical interface such as a switch or a button or a graphic interface is used.

The electronic apparatus 51 is not limited to apparatus of a specific field as long as it has a function to display an image and video produced therein or input from the external.

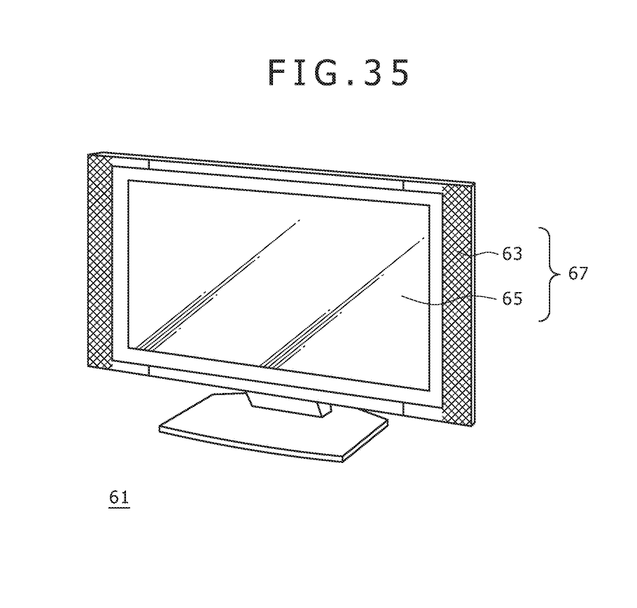

FIG. 35 is an appearance example of a television receiver as electronic apparatus to which the organic EL panel is applied.

On the front face of the casing of a television receiver 61, a display screen 67 composed of a front panel 63, a filter glass 65, and so on is disposed. The display screen 67 corresponds to the organic EL panel described for the form example.

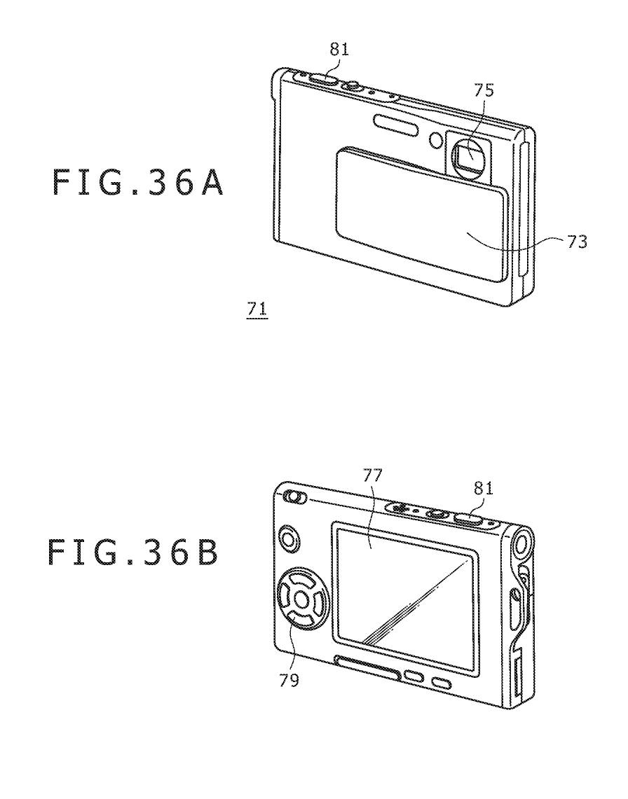

Furthermore, e.g. a digital camera is available as this kind of electronic apparatus 51. FIGS. 36A and 36B show an appearance example of a digital camera 71. FIG. 36A shows an appearance example of the front-face side (imaging-subject side), and FIG. 36B shows an appearance example of the back-face side (photographer side).

The digital camera 71 includes a protective cover 73, an imaging lens unit 75, a display screen 77, a control switch 79, and a shutter button 81. The display screen 77 corresponds to the organic EL panel described for the form example.

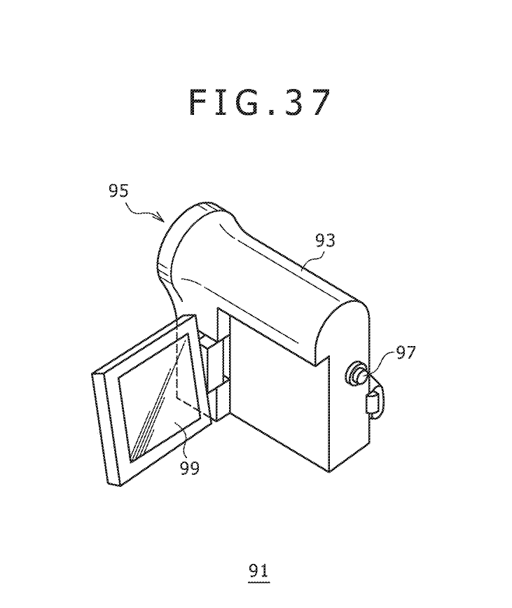

Furthermore, e.g. a video camera is available as this kind of electronic apparatus 51. FIG. 37 shows an appearance example of a video camera 91.

The video camera 91 includes an imaging lens 95 that is disposed on the front side of a main body 93 and used to capture an image of a subject, a start/stop switch 97 for imaging, and a display screen 99. The display screen 99 corresponds to the organic EL panel described for the form example.

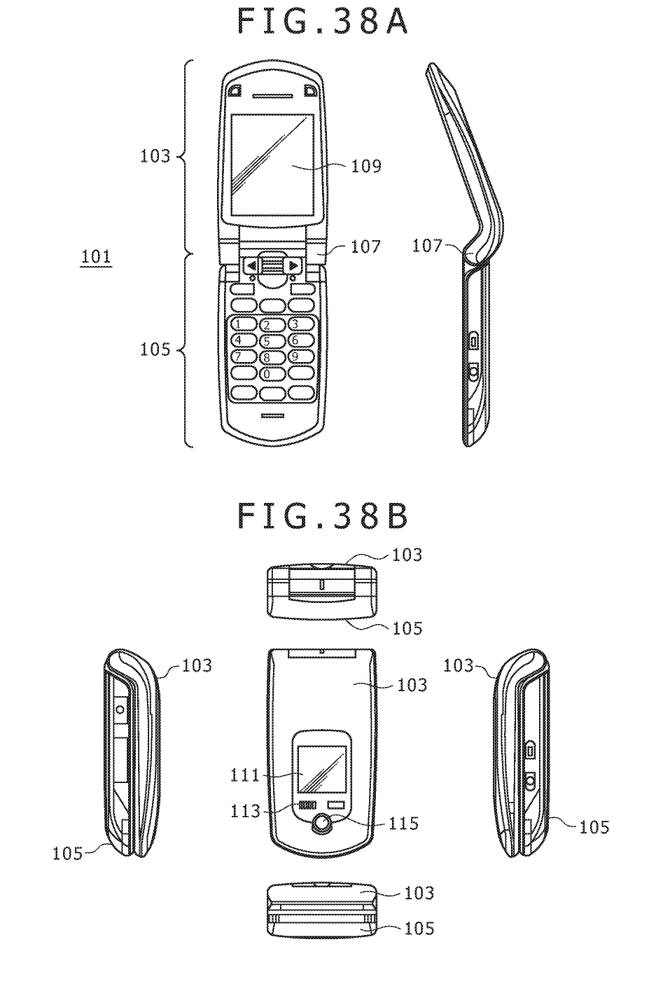

Furthermore, e.g. a portable terminal device is available as this kind of electronic apparatus 51. FIG. 38 is an appearance example of a cellular phone 101 as the portable terminal device. The cellular phone 101 shown in FIGS. 38A and 38B are foldable type. FIG. 38A shows an appearance example of the casing-opened state, and FIG. 38B shows an appearance example of the casing-closed state.

The cellular phone 101 includes an upper casing 103, a lower casing 105, a connection (hinge, in this example) 107, a display screen 109, an auxiliary display screen 111, a picture light 113, and an imaging lens 115. The display screen 109 and the auxiliary display screen 111 correspond to the organic EL panel described for the form example.

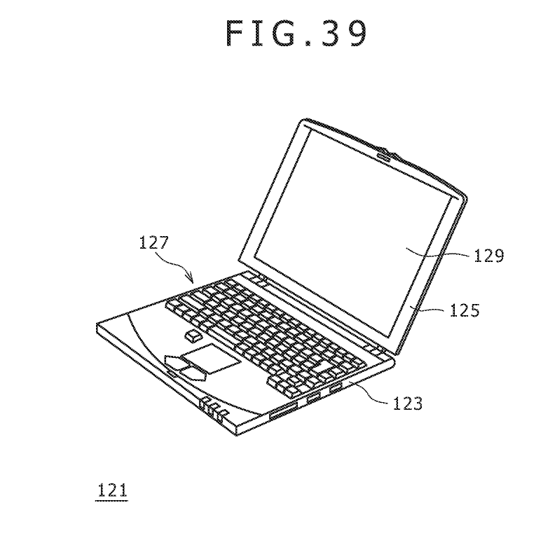

Furthermore, e.g. a computer is available as this kind of electronic apparatus 51. FIG. 39 shows an appearance example of a notebook computer 121.

The notebook computer 121 includes a lower casing 123, an upper casing 125, a keyboard 127, and a display screen 129. The display screen 129 corresponds to the organic EL panel described for the form example.

Besides the above-described devices, an audio reproduction device, a game machine, an electronic book, an electronic dictionary, and so on are available as the electronic apparatus 51.

### (D-9) Other Display Device Examples

The above description has dealt with the form examples applied to an organic EL panel.

However, the above-described drive technique can also be applied to other EL display devices. For example, the drive technique can also be applied to a display device including arranged LEDs and other display devices in which light-emitting elements having a diode structure are arranged on the screen. In addition, the drive technique can also be applied to a display device in which inorganic EL elements are arranged on the screen.

### (D-10) Other Notes

Various modifications might be incorporated into the above-described form examples without departing from the scope of the present invention. In addition, various modifications and applications that are created or combined based on the description of the present specification are also available.

What is claimed is:

1. An electro luminescent display panel having a pixel structure corresponding to an active-matrix drive system, the electro luminescent display panel comprising a current supply line configured to be connected to a plurality of pixel circuits in common, a first line width of an intersection part of the current supply line with a signal line being smaller than a second line width of another part of the current supply line,
wherein a driving of the current supply line is controlled with potentials of binary or more values, and
wherein a timing of a potential change of the current supply line corresponding to a given row is within a period of writing of a signal line potential on another row.

2. The electro luminescent display panel according to claim 1, wherein a mobility correction is executed within the period of the writing of the signal line potential.

3. The electro luminescent display panel according to claim 1, wherein the timing of the potential change of the current supply line corresponding to the given row is within a period of a threshold correction on another row.

4. The electro luminescent display panel according to claim 1, wherein the pixel structure has a top-emission structure.
